(19) United States
(12) Patent Application Publication
(10) Pub. No.: US 2024/0290767 A1
(43) Pub. Date: Aug. 29, 2024

(54) DISPLAY DEVICE AND MANUFACTURING METHOD OF DISPLAY DEVICE

(71) Applicant: LG Display Co., Ltd., Seoul (KR)

(72) Inventors: Dojin KIM, Seoul (KR); Hanyoung YANG, Goyang-si (KR)

(73) Assignee: LG Display Co., Ltd., Seoul (KR)

(21) Appl. No.: 18/584,744

(22) Filed: Feb. 22, 2024

(30) Foreign Application Priority Data
Feb. 28, 2023 (KR) 10-2023-0027192

(51) Int. Cl. H01L 25/16; H01L 33/62

(52) U.S. Cl. CPC H01L 25/167; H01L 33/62; H01L 2933/0066

(57) ABSTRACT

A manufacturing method of a display device may include: transferring light emitting diodes onto a display panel using an alignment key on a wafer; determining a defective light emitting diode which is missed or misplaced from a transferring position; and transferring at least one light emitting diode for repairing the defective light emitting diode onto the display panel using a repair alignment key. The method can improve a repair process efficiency. In a display device, at least one light emitting diode of a pixel may be in a second electrode area of an electrode area, and each of other light emitting diodes of the pixel may be disposed in a first electrode area of an electrode area of the pixel but not in a second electrode area of the electrode area. Some corresponding light emitting diodes of two pixels may be separated by a distance different from a pixel distance.

### CROSS-REFERENCE TO RELATED APPLICATIONS

This application claims the benefit of and priority to Korean Patent Application No. 10-2023-0027192 filed on Feb. 28, 2023, the entirety of which is incorporated herein by reference for all purposes.

### BACKGROUND

### 1. Technical Field

The present disclosure relates to a display device, and particularly to, for example, without limitation, a manufacturing method of a display device and a repairing method of a display device using a light emitting diode (LED).

### 2. Description of the Related Art

Display devices may be used for, among others, a computer monitor, a television, or a cellular phone, or the like, and a display device may employ, for example, an organic light emitting display (OLED) device which is a self-emitting device, a liquid crystal display (LCD) device which requires a separate light source, or the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the light emitting diode is formed of an inorganic material, rather than an organic material, reliability is excellent so that a lifespan thereof is longer than that of the liquid crystal display device or the organic light emitting display device. Further, the light emitting diode has a fast lighting speed, excellent luminous efficiency, and a strong impact resistance so that a stability is excellent and an image having a high luminance can be displayed.

The description of the related art should not be assumed to be prior art merely because it is mentioned in or associated with this section. The description of the related art may include information that describes one or more aspects of the subject technology, and the description in this section does not limit the invention.

### SUMMARY

One or more aspects of the present disclosure are directed to providing a manufacturing method of a display device which improves an efficiency of a repair transfer process.

One or more other aspects of the present disclosure are directed to providing a manufacturing method of a display device which improves an alignment precision between a plurality of light emitting diodes.

One or more other aspects of the present disclosure are directed to providing a manufacturing method of a display device which improves a yield and a productivity by precisely aligning a plurality of light emitting diodes.

One or more other aspects of the present disclosure are directed to providing a display device resulting from a manufacturing method and advantages described herein and other aspects clearly understood by those skilled in the art from the descriptions herein.

Aspects of the present disclosure are not limited to the above-mentioned aspects, and other aspects, which are not mentioned above, can be clearly understood by those skilled in the art from the descriptions herein.

According to one or more aspects of the present disclosure, a manufacturing method of a display device may include: transferring a plurality of light emitting diodes onto a display panel using a main alignment key disposed on a wafer; determining a defective light emitting diode which is missed or misplaced from a transferring position; and transferring at least one light emitting diode for repairing the defective light emitting diode onto the display panel using a repair alignment key disposed on a second wafer, wherein the second wafer is same as or different from the wafer. The manufacturing method can improve a repair process efficiency of a defective light emitting diode.

According to one or more aspects of the present disclosure, a display device may include: a display panel; an active area and a non-active area surrounding the active area; and a plurality of pixels in the active area. Each pixel may include electrode areas; each electrode area may include a first electrode area and a second electrode area adjacent to the first electrode area; positions of the first and second electrode areas relative to each other may be the same for all of the electrode areas; each pixel may include a plurality of light emitting diodes, and each light emitting diode may be disposed in at least one of the first electrode area or the second electrode area of a corresponding electrode area; the plurality of pixels may include a first pixel; at least one light emitting diode of the first pixel may be disposed in the second electrode area of the corresponding electrode area of the first pixel; and each of other light emitting diodes of the first pixel may be disposed in the first electrode area of the corresponding electrode area of the first pixel but not in the second electrode area of the corresponding electrode area of the first pixel.

According to one or more aspects of the present disclosure, a display device may include: a display panel; an active area and a non-active area; and a plurality of pixels arranged in the active area, the plurality of pixels forming a matrix. Each pixel may include a plurality of light emitting diodes arranged in rows and columns, the plurality of light emitting diodes for emitting light; the plurality of pixels may include a first pixel and a second pixel adjacent to the first pixel; at least one light emitting diode of the first pixel may be separated by a first distance from a light emitting diode at a corresponding row and a corresponding column of the second pixel; each of the other light emitting diodes of the first pixel may be separated by a second distance from a light emitting diode at a corresponding row and a corresponding column of the second pixel; and the first distance may be different from the second distance.

Other detailed matters of one or more example embodiments are included in the detailed description and the drawings.

In the manufacturing process of a display device according to one or more example embodiments of the present disclosure, an efficiency of a repair transfer process may be increased.

An alignment precision between a plurality of light emitting diodes of a display device manufactured by the manufacturing process of a display device according to one or more example embodiments of the present disclosure may be improved.

In the manufacturing process of a display device according to one or more example embodiments of the present disclosure, a productivity of the manufacturing process of the display device and a yield of the manufacturing process may be improved.

A display device resulting from a manufacturing method and advantages described herein exhibit, among others, improved quality and reliability.

The effects according to one or more aspects of the present disclosure are not limited to the foregoing descriptions, and other effects are included in the present specification.

Other aspects, effects, devices, methods, features and advantages will be, or will become, apparent to one with skill in the art upon examination of the drawings and detailed description herein. It is intended that all such aspects, effects, devices, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

In the drawings:

FIG. 1 is a schematic diagram of a display device according to one or more example embodiments of the present disclosure;

FIG. 2A is a partial cross-sectional view of a display device according to one or more example embodiments of the present disclosure;

FIG. 2B is a perspective view of a tiling display device according to one or more example embodiments of the present disclosure.

FIG. 3 is a plan view of a display panel of a display device according to one or more example embodiments of the present disclosure;

FIGS. 4A and 4B are plan views illustrating a pixel area of a display device according to one or more example embodiments of the present disclosure;

FIG. 5 is a cross-sectional view of a display device according to one or more example embodiments of the present disclosure.

FIG. 6 is a process flowchart for describing a manufacturing method of a display device according to one or more example embodiments of the present disclosure;

FIG. 7 is a process flowchart for describing a main transfer process of a manufacturing method of a display device according to one or more example embodiments of the present disclosure;

FIG. 8 is a view illustrating a wafer used for a manufacturing method of a display device according to one or more example embodiments of the present disclosure;

FIG. 9 is a view illustrating a second alignment key disposed on a wafer used for a manufacturing method of a display device according to one or more example embodiments of the present disclosure;

FIG. 10 is a view illustrating a donor used for a manufacturing method of a display device according to one or more example embodiments of the present disclosure;

FIG. 11 is a cross-sectional view for describing a step of bonding a wafer and a donor substrate in a main transfer process of a manufacturing method of a display device according to one or more example embodiments of the present disclosure;

FIG. 12A is a cross-sectional view for describing a step of transferring a plurality of light emitting diodes of a wafer onto a donor substrate in a main transfer process of a manufacturing method of a display device according to one or more example embodiments of the present disclosure;

FIG. 12B is a front view for describing a step of transferring a plurality of light emitting diodes of a wafer onto a donor substrate in a main transfer process of a manufacturing method of a display device according to one or more example embodiments of the present disclosure;

FIG. 13 is a cross-sectional view for describing a step of bonding a donor substrate and a display panel in a main transfer process of a manufacturing method of a display device according to one or more example embodiments of the present disclosure;

FIG. 14 is a front view for describing a step of transferring a plurality of light emitting diodes of a donor substrate onto a display panel in a main transfer process of a manufacturing method of a display device according to one or more example embodiments of the present disclosure;

FIG. 15 is a process flowchart for describing a repair transfer process of a manufacturing method of a display device according to one or more example embodiments of the present disclosure;

FIG. 16 is a cross-sectional view for describing a step of bonding a wafer and a donor substrate in a repair transfer process of a manufacturing method of a display device according to one or more example embodiments of the present disclosure;

FIG. 17A is a cross-sectional view for describing a step of transferring at least one light emitting diode of a wafer onto a donor substrate in a repair transfer process of a manufacturing method of a display device according to one or more example embodiments of the present disclosure;

FIG. 17B is a front view for describing a step of transferring a plurality of light emitting diodes of a wafer onto a donor substrate in a repair transfer process of a manufacturing method of a display device according to one or more example embodiments of the present disclosure;

FIG. 18 is a cross-sectional view for describing a step of bonding a donor substrate and a display panel in a repair transfer process of a manufacturing method of a display device according to one or more example embodiments of the present disclosure; and

FIG. 19 is a front view for describing a step of transferring a plurality of light emitting diodes of a donor substrate onto a display panel in a repair transfer process of a manufacturing method of a display device according to one or more example embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, member, part, region, area, portion, or the like) surrounds or is “provided,” “disposed,” “connected,” “coupled,” or the like in, on, with or to another element may be understood, for example, as that at least a portion of the element surrounds or is provided, disposed, connected, coupled, or the like in, on, with or to at least a portion of another element. The phrase “through” may be understood, for example, to be at least partially through or entirely through. The phase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “some elements,” “a portion,” “portions,” “at least a portion,” “at least portions,” “a part,” “at least a part,” “parts,” “at least parts,” “one or more,” or the like of the plurality of elements can represent (i) one element of the plurality of elements, (ii) a part of the plurality of elements, (iii) parts of the plurality of elements, (iv) multiple elements of the plurality of elements, or (v) all of the plurality of elements. Moreover, at least a portion (or a part) of an element can represent (i) a portion (or a part) of the element, (ii) one or more portions (or parts) of the element, or (iii) the element, or the entirety of the element. A phrase that a plurality of first elements are connected to a plurality of second elements may describe, for example, that at least a part (or one or more first elements) of a plurality of first elements are connected to at least a part (or one or more second elements) of a plurality of second elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

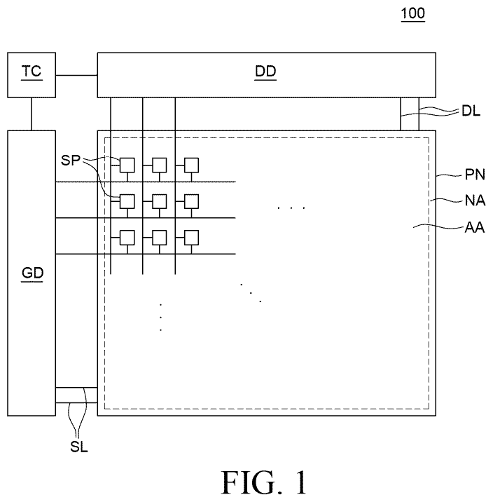

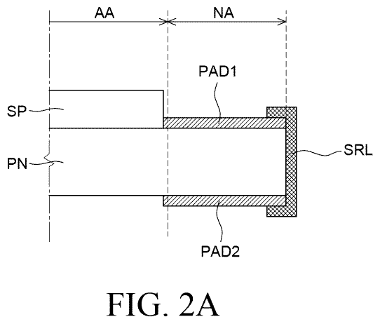

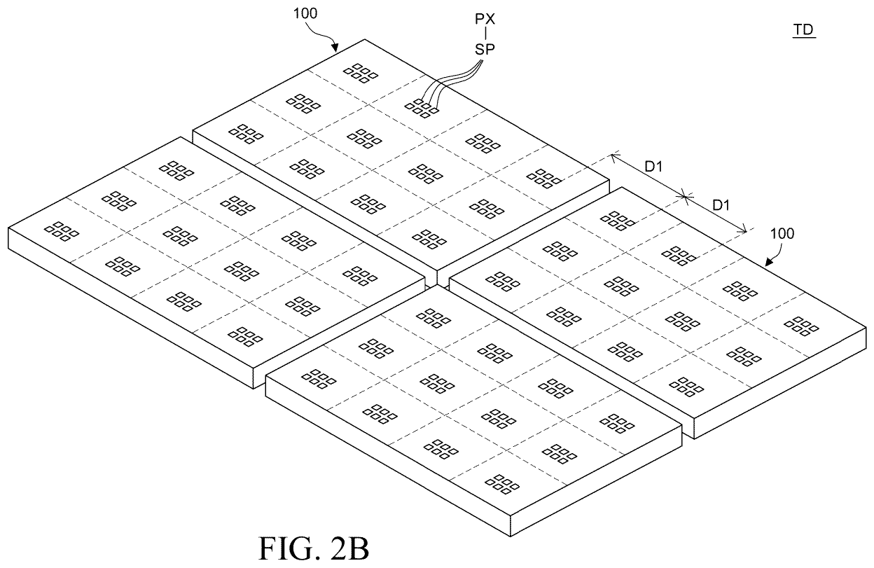

FIG. 1 is a schematic diagram of a display device according to one or more example embodiments of the present disclosure. FIG. 2A is a partial cross-sectional view of a portion of a display device according to one or more example embodiments of the present disclosure. FIG. 2B is a perspective view of a tiling display device according to one or more example embodiments of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL in accordance with a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line VL1, a low potential power line VL2, a reference line, and the like.

In the display device 100 or the display panel PN, an active area AA and the non-active area NA enclosing or surrounding the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP may form one pixel, where n is a whole number greater than 0. In each of the plurality of sub pixels SP, a light emitting diode, a thin film transistor for driving the light emitting diode, and the like may be disposed. The plurality of light emitting diodes may be defined in different manners depending on the type of the display panel PN. For example, when the display panel PN is an inorganic light emitting display panel, the light emitting diode may be a light emitting diode or a micro light emitting diode.

In the active area AA, a plurality of wiring lines which transmits various signals to the plurality of sub pixels SP is disposed. For example, the plurality of wiring lines may include (i) a plurality of data lines DL, each of which may supply a data voltage to a corresponding one of the plurality of sub pixels SP, (ii) a plurality of scan lines SL, each of which may supply a scan signal to a corresponding one of the plurality of sub pixels SP, and (iii) the like. The plurality of scan lines SL extends in one direction in the active area AA to be connected to the plurality of sub pixels SP and the plurality of data lines DL extends in a direction different from the one direction in the active area AA to be connected to the plurality of sub pixels SP. In addition, in the active area AA, a low potential power line VL2, a high potential power line VL1, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, a driving integrated circuit (IC), such as a gate driver IC or a data driver IC, or the like may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board. The data driver DD and the timing controller TC may be electrically connected to the display panel PN by bonding the flexible film and the printed circuit board to the pad electrode formed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel with substantially no bezel may be implemented.

Specifically, referring to FIGS. 2A and 2B, in the non-active area NA of the display panel PN, a plurality of pad electrodes PAD1 and PAD2 for transmitting various signals to the plurality of sub pixels SP is disposed. For example, in the non-active area NA on the front surface of the display panel PN, a first pad electrode PAD1 which transmits a signal to the plurality of sub pixels SP is disposed. In the non-active area NA on the rear surface of the display panel PN, a second pad electrode PAD2 which is electrically connected to a driving component, such as a flexible film and the printed circuit board, is disposed. That is, on the front surface of the display panel PN on which images are displayed, only a plurality of pad areas PA1 and PA2 of the non-active area NA in which the first pad electrode PAD1 is disposed may be formed at a minimum.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

The side line SRL is disposed along a side surface of the display panel PN. The side line SRL may electrically connect a first pad electrode PAD1 on the front surface of the display panel PN and a second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signal transmitting path from the front surface of the display panel PN to the side surface and the rear surface is formed to minimize an area of the non-active area NA on the front surface of the display panel PN.

Referring to FIG. 2B, a tiling display device 100 having a large screen size may be implemented by connecting a plurality of display devices 100. At this time, as illustrated in FIG. 2A, when the tiling display device 100 is implemented using a display device 100 with a minimized bezel, a seam area in which an image between the display devices 100 is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, a constant distance D1 between pixels PX between the display devices 100 is configured to minimize the seam area.

However, FIGS. 2A and 2B are illustrative so that the display device 100 according to one or more example embodiments of the present disclosure may be a general display device 100 with a bezel, but is not limited thereto.

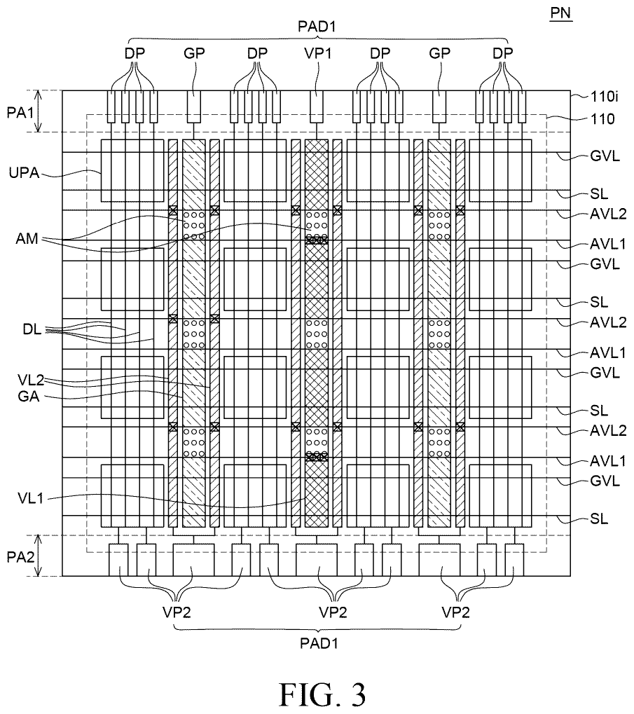

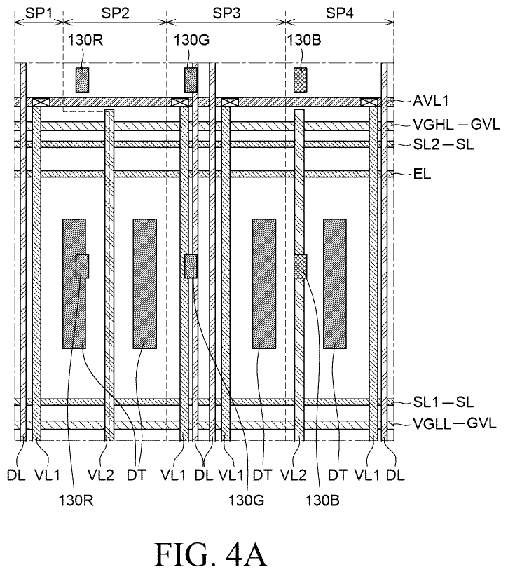

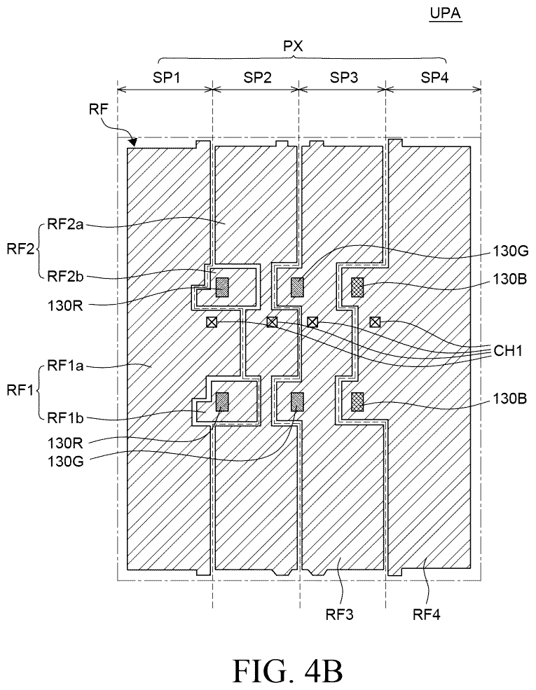

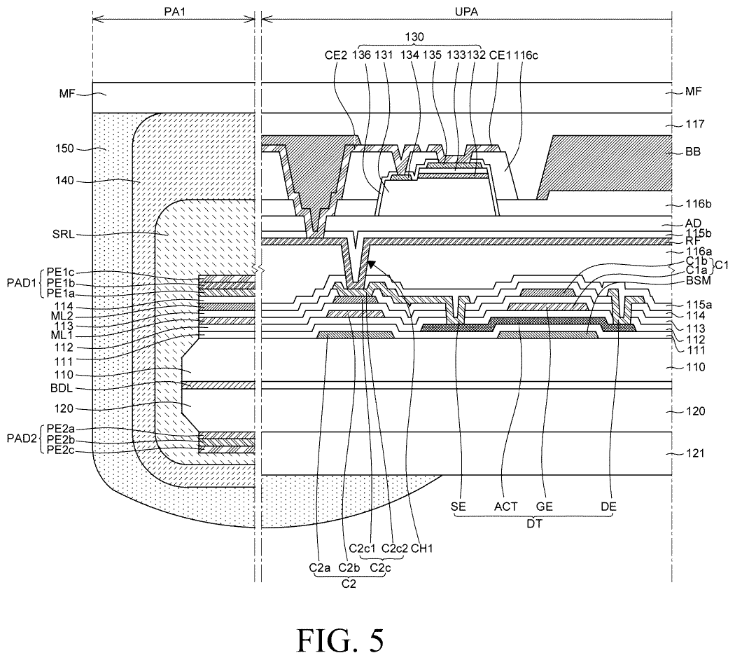

FIG. 3 is a plan view of a display panel of a display device according to one or more example embodiments of the present disclosure. FIGS. 4A and 4B are plan views illustrating a pixel area of a display device according to one or more example embodiments of the present disclosure. FIG. 5 is a cross-sectional view of a display device according to one or more example embodiments of the present disclosure. For the convenience of description, in FIG. 4A, only the plurality of light emitting diodes, a driving transistor DT of the pixel circuit, and a plurality of wiring lines are illustrated and in FIG. 4B, only a plurality of reflection plates and a plurality of light emitting diodes are illustrated. In one or more aspects, the elements and notations illustrated in FIG. 4A but not shown in FIG. 4B may be deemed to be present in FIG. 4B, and the elements and notations illustrated in FIG. 4B but not shown in FIG. 4A may be deemed to be present in FIG. 4A.

First, referring to FIGS. 3 to 5, the display panel PN includes a first substrate 110. The first substrate 110 is a substrate which supports components disposed above the display device 100 and may be an insulating substrate. A plurality of pixels PX is formed on the first substrate 110 to display images. For example, the first substrate 110 may be formed of glass or resin. Further, the first substrate 110 may include polymer or plastic. In some example embodiments, the first substrate 110 may be formed of a plastic material having flexibility.

Referring to FIG. 3, in the first substrate 110, a plurality of pixel areas UPA, a plurality of gate driving areas GA, and a plurality of pad areas PA1 and PA2 are disposed. Among them, the plurality of pixel areas UPA and the plurality of gate driving areas GA may be included in the active area AA of the display panel PN.

First, the plurality of pixel areas UPA is areas in which the plurality of pixels PX is disposed. The plurality of pixel areas UPA may be disposed by forming a plurality of rows and a plurality of columns. Each of the plurality of pixels disposed in the plurality of pixel areas UPA includes a plurality of sub pixels SP. Each of the plurality of sub pixels SP includes a light emitting diode and a pixel circuit to independently emit light.

The plurality of gate driving areas GA is areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The plurality of pad areas PA1 and PA2 is areas in which a plurality of first pad electrodes PAD1 is disposed. The plurality of first pad electrodes PAD1 may transmit various signals to various wiring lines extending in a column direction in the active area AA. For example, the plurality of first pad electrodes PAD1 includes a data pad DP, a gate pad GP, a high potential power pad VP1, and a low potential power pad VP2. The data pad DP transmits a data voltage to the data line DL and the gate pad GP transmits a clock signal, a start signal, a gate low voltage, a gate high voltage, and the like for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas PA1 and PA2 includes a plurality of first pad areas PA1 located at an upper edge of the display panel PN and a plurality of second pad areas PA2 located at a lower edge of the display panel PN. At this time, in the plurality of first pad areas PA1 and the plurality of second pad areas PA2, different types of first pad electrodes PAD1 may be disposed. For example, in the plurality of first pad areas PA1, among the plurality of first pad electrodes PAD1, the data pad DP, the gate pad GP, and the high potential power pad VP1 may be disposed and in the plurality of second pad areas PA2, the low potential power pad VP2 may be disposed.

At this time, the plurality of first pad electrodes PAD1 may be formed to have different sizes, respectively. For example, the plurality of data pads DP which is connected to the plurality of data lines DL one to one may have a narrower width and the high potential power pad VP1, the low potential power pad VP2, and the gate pad GP may have a larger width. However, widths of the data pad DP, the gate pad GP, the high potential power pad VP1, and the low potential power pad VP2 illustrated in FIG. 3 are illustrative so that the first pad electrode PAD1 may be configured in various sizes, but is not limited thereto.

In the meantime, in order to reduce the bezel of the display panel PN, an edge of the display panel PN may be cut to be removed. The plurality of pixels PX, the plurality of wiring lines, and the plurality of first pad electrodes PAD1 are formed on an initial first substrate 110i and an edge part of the initial first substrate 110i is ground to reduce the bezel area. During the grinding process, a part of the initial first substrate 110i is removed to form a first substrate 110 with a smaller size. At this time, parts of the plurality of first pad electrodes PAD1 and wiring lines disposed at the edge of the first substrate 110 may be removed. Accordingly, only a part of the plurality of first pad electrodes PAD1 may remain on the first substrate 110.

Next, the plurality of data lines DL which extends in a column direction from the plurality of first pad electrodes PAD1 is disposed on the first substrate 110 of the display panel PN. The plurality of data lines DL may extend from the plurality of data pads DP of the plurality of first pad areas PA1 toward the plurality of pixel areas UPA. The plurality of data lines DL may extend in a column direction and may be disposed to overlap the plurality of pixel areas UPA. Therefore, each of the plurality of data lines DL may transmit the data voltage to the pixel circuit of a corresponding one of the plurality of sub pixels SP.

The plurality of high potential power lines VL1 extending in the column direction is disposed on the first substrate 110 of the display panel PN. Some of the plurality of high potential power lines VL1 extend from the high potential power pad VP1 of the plurality of first pad areas PA1 to the plurality of pixel areas UPA to transmit the high potential power voltage to the light emitting diodes of the plurality of sub pixels SP, respectively. The others of the plurality of high potential power lines VL1 may be electrically connected to the other high potential power line VL1 by means of an auxiliary high potential power line AVL1 to be described below. In FIG. 3, for the convenience of description, even though it is illustrated that one high potential power line VL1 and one high potential power pad VP1 are disposed, a plurality of high potential power lines VL1 and high potential power pads VP1 may be disposed.

The plurality of low potential power lines VL2 extending in the column direction is disposed on the first substrate 110 of the display panel PN. At least some of the plurality of low potential power lines VL2 extend from the low potential power pad VP2 of the plurality of second pad areas PA2 to the plurality of pixel areas UPA, and each of such low potential power lines VL2 may transmit the low potential power voltage to the pixel circuit of a corresponding one of the plurality of sub pixels SP. The others of the plurality of low potential power lines VL2 may be electrically connected to the other low potential power line VL2 by means of an auxiliary low potential power line AVL2 to be described below.

The plurality of scan lines SL extending in the row direction is disposed on the first substrate 110 of the display panel PN. The plurality of scan lines SL extends in the row direction and may be disposed across the plurality of pixel areas UPA and the plurality of gate driving areas GA. The plurality of scan lines SL may transmit the scan signals from the gate driver GD to the pixel circuits of the plurality of sub pixels SP.

A plurality of auxiliary high potential power lines AVL1 extending in the row direction is disposed on the first substrate 110 of the display panel PN. The plurality of auxiliary high potential power lines AVL1 may be disposed in an area between the plurality of pixel areas UPA. The plurality of auxiliary high potential power lines AVL1 extending in the row direction is electrically connected to the plurality of high potential power lines VL1 extending in the column direction through contact holes and may form a mesh structure. Therefore, the plurality of auxiliary high potential power lines AVL1 and the plurality of high potential power lines VL1 are configured to form a mesh structure to minimize voltage drop and voltage deviation.

A plurality of auxiliary low potential power lines AVL2 extending in the row direction is disposed on the first substrate 110 of the display panel PN. The plurality of auxiliary low potential power lines AVL2 may be disposed in an area(s) between the plurality of pixel areas UPA. The plurality of auxiliary low potential power lines AVL2 extending in the row direction is electrically connected to the plurality of low potential power lines VL2 extending in the column direction through contact holes to form a mesh structure. Therefore, the plurality of auxiliary low potential power lines AVL2 and the plurality of low potential power lines VL2 are configured to form a mesh structure to reduce a resistance of the wiring line and minimize voltage deviation.

Referring to FIGS. 3 and 4A, the plurality of gate driving lines GVL extending in the row direction and the column direction is disposed on the first substrate 110 of the display panel PN. Some of the plurality of gate driving lines GVL extend from the gate pad GP of the plurality of first pad areas PA1 to the gate driving area GA to transmit a signal(s) to the gate driver GD. The others of the plurality of gate driving lines GVL extend in the row direction and may transmit the signal(s) to the gate drivers GD of the plurality of gate driving areas GA. Therefore, various signals are transmitted from the gate driving line GVL to the gate driver GD to drive the gate driver GD.

The plurality of gate driving lines GVL may include wiring lines which transmit a clock signal, a start signal, a gate high voltage, a gate low voltage, and the like to the gate driver GD. Therefore, various signals are transmitted from the gate driving line GVL to the gate driver GD to drive the gate driver GD.

For example, referring to FIG. 4A, the plurality of gate driving lines GVL may include gate power lines VGLL and VGHL which transmit power voltages to the gate driver GD of the gate driving area GA. The plurality of gate power lines VGLL and VGHL includes a first gate power line VGHL which transmits a gate high voltage to the gate driver GD and a second gate power line VGLL which transmits a gate low voltage to the gate driver GD.

A plurality of alignment marks AM is disposed in an area between the plurality of pixel areas UPA in the display panel PN, as illustrated in FIG. 3. The plurality of alignment marks AM is used for alignment during the manufacturing process of the display panel PN.

The plurality of alignment marks AM is disposed in the gate driving area GA of an area between the plurality of pixel areas UPA or may be disposed so as to overlap the high potential power line VL1. The plurality of alignment marks AM may be used to align the display panel PN and a donor. The display panel PN and the donor are aligned using the plurality of alignment marks AM, and the plurality of light emitting diodes disposed on the donor substrate may be transferred onto the display panel PN. For example, each of the plurality of alignment marks AM may have a circular ring shape, but is not limited thereto.

Hereinafter, the plurality of sub pixels SP of the pixel area UPA is described in more detail with reference to FIGS. 4A to 5.

Referring to FIGS. 4A and 4B, in one pixel area UPA, a plurality of sub pixels SP1, SP2, SP3, and SP4 which forms one pixel is disposed. For example, the plurality of sub pixels SP1, SP2, SP3, and SP4 may include a first sub pixel SP1, a second sub pixel SP2, a third sub pixel SP3, and a fourth sub pixel SP4 which emit different color light. For example, the first sub pixel SP1 and the second sub pixel SP2 are red sub pixels, the third sub pixel SP3 is a green sub pixel, and the fourth sub pixel SP4 is a blue sub pixel, but the present disclosure is not limited thereto.

Hereinafter, the description is made by assuming that one pixel includes one first sub pixel SP1, one second sub pixel SP2, one third sub pixel SP3, and one fourth sub pixel SP4, that is, two red sub pixels, one green sub pixel, and one blue sub pixel. However, the configuration of the pixel is not limited thereto.

Referring to FIG. 4A, as described above, a plurality of wiring lines which supplies various signals to the plurality of sub pixels SP1, SP2, SP3, and SP4 is disposed in the plurality of pixel areas UPA of the first substrate 110. For example, the plurality of data lines DL, the plurality of high potential power lines VL1, and the plurality of low potential power lines VL2 extending in the column direction may be disposed on the first substrate 110. For example, the plurality of emission control signal lines EL, the plurality of auxiliary high potential power lines AVL1, the plurality of auxiliary low potential power lines AVL2, the plurality of first scan lines SL1, and the plurality of second scan lines SL2 extending in the row direction may be disposed on the first substrate 110. The high potential power line VL1 extending in the column direction may be electrically connected to the auxiliary high potential power line AVL1 extending in the row direction through a contact hole(s). At this time, the emission control signal line EL transmits an emission control signal to the pixel circuits of the plurality of sub pixels SP1, SP2, SP3, and SP4 to control emission timings of the plurality of sub pixels SP1, SP2, SP3, and SP4, respectively.

Some gate driving lines GVL which transmit signals to a corresponding one of the plurality of gate drivers GD disposed to be spaced apart from each other with the pixel area UPA therebetween may be disposed across the pixel area UPA while extending in the row direction. For example, a first gate power line VGHL which supplies a gate high voltage to the gate driver GD and a second gate power line VGLL which supplies a gate low voltage may be disposed across the pixel area UPA.

In the meantime, even though it is illustrated that the plurality of scan lines SL includes a first scan line SL1 and a second scan line SL2, the configuration of the plurality of scan lines SL may vary depending on the pixel circuit configuration of the sub pixel SP, but is not limited thereto.

The pixel circuit for driving the light emitting diode is disposed in each of the plurality of sub pixels SP1, SP2, SP3, and SP4 on the first substrate 110. The pixel circuit may include a plurality of thin film transistors and a plurality of capacitors. In FIGS. 4A and 5, for the convenience of description, only a driving transistor DT, a first capacitor C1, and a second capacitor C2, among configurations of the pixel circuit are illustrated. However, the pixel circuit may further include a switching transistor, a sensing transistor, an emission control transistor, and the like, but is not limited thereto.

First, a light shielding layer BSM is disposed on the first substrate 110. The light shielding layer BSM blocks light which is incident to an active layer of the plurality of transistors to minimize a leakage current. For example, the light shielding layer BSM is disposed below the active layer ACT of the driving transistor DT to block light incident onto the active layer ACT. If light is irradiated onto the active layer ACT, a leakage current is generated, which deteriorates the reliability of the transistor. Accordingly, the light shielding layer BSM which blocks the light is disposed on the first substrate 110 to improve the reliability of the driving transistor DT. The light shielding layer BSM may be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 is disposed on the light shielding layer BSM. The buffer layer 111 may reduce permeation of moisture or impurities through the first substrate 110. For example, the buffer layer 111 may be configured by a single layer or a double layer of silicon oxide (SiOx) or silicon nitride (SiNx), but is not limited thereto. However, the buffer layer 111 may be omitted depending on a type of the first substrate 110 or a type of the thin film transistor, but is not limited thereto.

A driving transistor DT including an active layer ACT, a gate electrode GE, a source electrode SE, and a drain electrode DE is disposed on the buffer layer 111.

First, the active layer ACT of the driving transistor DT is disposed on the buffer layer 111. The active layer ACT may be formed of a semiconductor material such as an oxide semiconductor, amorphous silicon, or polysilicon, but is not limited thereto.

The gate insulating layer 112 is disposed on the active layer ACT. The gate insulating layer 112 is an insulating layer which electrically insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

A first interlayer insulating layer 113 and a second interlayer insulating layer 114 are disposed on the gate electrode GE. In the first interlayer insulating layer 113 and the second interlayer insulating layer 114, contact holes through which the source electrode SE and the drain electrode DE are connected to the active layer ACT are formed. The first interlayer insulating layer 113 and the second interlayer insulating layer 114 are insulating layers which protect components therebelow and may be configured by single layers or double layers of silicon oxide (SiOx) or silicon nitride (SiNx), but is not limited thereto.

The source electrode SE and the drain electrode DE which are electrically connected to the active layer ACT are disposed on the second interlayer insulating layer 114. The source electrode SE is connected to the second capacitor C2 and the first electrode 134 of the light emitting diode 130 and the drain electrode DE is connected to the other configuration of the pixel circuit. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a may be integrally formed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 therebetween.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a is disposed on the first substrate 110. The 2-1-th capacitor electrode C2a may be disposed on the same layer as the light shielding layer BSM and may be formed of the same material.

The 2-2-th capacitor electrode C2b is disposed on the buffer layer 111 and the gate insulating layer 112. The 2-2-th capacitor electrode C2b is disposed on the same layer as the gate electrode GE and may be formed of the same material.

The 2-3-th capacitor electrode C2c is disposed on the first interlayer insulating layer 113. The 2-3-th capacitor electrode C2c may be configured by a first layer C2c1 and a second layer C2c2. The first layer C2c1 of the 2-3-th capacitor electrode C2c may be formed on the same layer as the 1-2-th capacitor electrode C1b with the same material. The first layer C2c1 may be disposed to overlap the 2-1-th capacitor electrode C2a and the 2-2-th capacitor electrode C2b with the first interlayer insulating layer 113 therebetween.

The second layer C2c2 of the 2-3-th capacitor electrode C2c is disposed on the second interlayer insulating layer 114. The second layer C2c2 is a part extending from the source electrode SE of the driving transistor DT and may be connected to the first layer C2c1 through the contact hole of the second interlayer insulating layer 114.

Accordingly, the second capacitor C2 is electrically connected between the source electrode SE of the driving transistor DT and the light emitting diode 130 to increase capacitance inherent in the light emitting diode 130 and allow the light emitting diode 130 to emit light with a higher luminance.

A first passivation layer 115a is disposed on the driving transistor DT, the first capacitor C1, and the second capacitor C2. The first passivation layer 115a is an insulating layer which protects components below the first passivation layer 115a and may be configured by an inorganic material, such as silicon oxide (SiOx) or silicon nitride (SiNx), but is not limited thereto.

A first planarization layer 116a is disposed on the first passivation layer 115a. The first planarization layer 116a may planarize an upper portion of the pixel circuit including the driving transistor DT. The first planarization layer 116a may be configured by a single layer or a double layer, and for example, configured by benzocyclobutene or an acrylic organic material, but is not limited thereto.

Referring to FIGS. 4B and 5 together, a plurality of reflection plates RF is disposed on the first planarization layer 116a. The reflection plate RF is a configuration which reflects light emitted from the plurality of light emitting diodes 130 above the first substrate 110 and may be formed with a shape corresponding to each of the plurality of sub pixels SP1, SP2, SP3, and SP4. One reflection plate RF may be disposed to cover the most area of one sub pixel SP. The reflection plate RF reflects the light emitted from the light emitting diode 130 and may be also used as an electrode which electrically connects the light emitting diode 130 and the pixel circuit. Therefore, the reflection plate RF may include various conductive layers in consideration of a light reflection efficiency and a resistance. For example, the reflection plate RF may use an opaque conductive layer such as silver (Ag), aluminum (Al), molybdenum (Mo), titanium (Ti), or an alloy thereof and a transparent conductive layer such as indium tin oxide, but the structure of the reflection plate RF is not limited thereto.

The reflection plate RF includes a first reflection plate RF1 corresponding to the first sub pixel SP1, a second reflection plate RF2 corresponding to the second sub pixel SP2, a third reflection plate RF3 corresponding to the third sub pixel SP3, and a fourth reflection plate RF4 corresponding to the fourth sub pixel SP4.

The first reflection plate RF1 includes a 1-1-th reflection plate RF1a overlapping most of the first sub pixel SP1 and a 1-2-th reflection plate RF1b overlapping the red light emitting diode 130R of the first sub pixel SP1. A 1-1-th reflection plate RF1a may reflect light emitted from the red light emitting diode 130R above the red light emitting diode 130R. The 1-1-th reflection plate RF1a may be electrically connected to the source electrode SE of the driving transistor DT and the second capacitor C2 through a first contact hole CH1 of the first planarization layer 116a and the first passivation layer 115a. Therefore, the 1-1-th reflection plate RF1a may electrically connect the driving transistor DT and the first electrode 134 of the red light emitting diode 130R. The 1-2-th reflection plate RF1b may reflect light emitted from the red light emitting diode 130R above the red light emitting diode 130R. The 1-2-th reflection plate RF1b may serve as an electrode which electrically connects the second electrode 135 of the red light emitting diode 130R and the high potential power line VL1.

The second reflection plate RF2 includes a 2-1-th reflection plate RF2a overlapping most of the second sub pixel SP2 and a 2-2-th reflection plate RF2b overlapping the red light emitting diode 130R of the second sub pixel SP2. The 2-1-th reflection plate RF2a may reflect light emitted from the red light emitting diode 130R above the red light emitting diode 130R. The 2-1-th reflection plate RF2a is electrically connected to the source electrode SE of the driving transistor DT and the second capacitor C2 through the first contact hole CH1 to transmit a driving current from the driving transistor DT to the first electrode 134 of the red light emitting diode 130R. The 2-2-th reflection plate RF2b may be used as an electrode which reflects the light emitted from the red light emitting diode 130R above the red light emitting diode 130R and electrically connects the second electrode 135 of the red light emitting diode 130R to the high potential power line VL1.

The third reflection plate RF3 may be formed as one third reflection plate RF3 which overlaps the entire third sub pixel SP3. The third reflection plate RF3 may reflect light emitted from the green light emitting diode 130G of the third sub pixel SP3 above the green light emitting diode 130G. The third reflection plate RF3 is electrically connected to the source electrode SE of the driving transistor DT and the second capacitor C2 through the first contact hole CH1 to transmit a driving current from the driving transistor DT to the first electrode 134 of the green light emitting diode 130G.

The fourth reflection plate RF4 may be formed as one fourth reflection plate RF4 which overlaps the entire fourth sub pixel SP4. The fourth reflection plate RF4 may reflect light emitted from the blue light emitting diode 130B of the fourth sub pixel SP4 above the blue light emitting diode 130B. The fourth reflection plate RF4 is electrically connected to the source electrode SE of the driving transistor DT and the second capacitor C2 through the first contact hole CH1 to transmit a driving current from the driving transistor DT to the first electrode 134 of the blue light emitting diode 130B.

In the meantime, even though it has been described that the first sub pixel SP1 and the second sub pixel SP2 are formed with two reflection plates and the third sub pixel SP3 and the fourth sub pixel SP4 are formed with one reflection plate, the reflection plate RF may be designed in various manners. For example, only one reflection plate may be disposed in all the plurality of sub pixels SP1, SP2, SP3, and SP4, like the third sub pixel SP3 and the fourth sub pixel SP4 or a plurality of reflection plates may be disposed in all the sub pixels like the first sub pixel SP1 and the second sub pixel SP2, but the reflection plate is not limited thereto.

Further, it has been described that the red light emitting diode 130R of each of the first sub pixel SP1 and the second sub pixel SP2 is electrically connected to the high potential power line VL1 through the 1-2-th reflection plate RF1b and the 2-2-th reflection plate RF2b. However, all the red light emitting diode 130R, the green light emitting diode 130G, and the blue light emitting diode 130B may be separately connected to the high potential power line VL1 without the reflection plate RF, but are not limited thereto.

Referring to FIG. 5, the second passivation layer 115b is disposed on the plurality of reflection plates RF. The second passivation layer 115b is an insulating layer which protects components below the second passivation layer 115b and may be configured by a single layer or a double layer of silicon oxide (SiOx) or silicon nitride (SiNx), but is not limited thereto.

An adhesive layer AD is disposed on the second passivation layer 115b. The adhesive layer AD is formed on the entire surface of the first substrate 110 to fix the light emitting diode 130 disposed on the adhesive layer AD. The adhesive layer AD may be formed of a photo curable adhesive material which is cured by light. For example, the adhesive layer AD may be formed of an acrylic material including a photoresist, but is not limited thereto. The adhesive layer AD may be formed on the entire surface of the first substrate 110 excluding a plurality of pad areas PA1 and PA2 in which the first pad electrode PAD1 is disposed.

The plurality of light emitting diodes 130 is disposed in the plurality of sub pixels SP on the adhesive layer AD. Each of the plurality of light emitting diodes 130 includes an element which emits light by a current. The plurality of light emitting diodes 130 may include a red light emitting diode 130R which emits red light, a green light emitting diode 130G which emits green light, and a blue light emitting diode 130B which emits blue light and may implement light with various colors including white by a combination thereof. For example, the light emitting diode 130 may be a light emitting diode or a micro light emitting diode, but is not limited thereto.

One red light emitting diode 130R is disposed in each of the first sub pixel SP1 and the second sub pixel SP2, one pair of green light emitting diodes 130G is disposed in the third sub pixel SP3, and one pair of blue light emitting diodes 130B is disposed in the fourth sub pixel SP4. That is, two red light emitting diodes 130R, two green light emitting diodes 130G, and two blue light emitting diodes 130B may be disposed in one pixel. At this time, each of the red light emitting diodes 130R is connected to the driving transistor DT of a corresponding one of the first sub pixel SP1 and the second sub pixel SP2 to be individually driven. In contrast, one pair of green light emitting diodes 130G of the third sub pixel SP3 and one pair of blue light emitting diodes 130B of the fourth sub pixel SP4 are connected to one driving transistor DT in parallel to be driven.

Each of the plurality of light emitting diodes 130 includes a first semiconductor layer 131, an emission layer 132, a second semiconductor layer 133, a first electrode 134, and a second electrode 135.

The first semiconductor layer 131 is disposed on the adhesive layer AD and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium, tin (Sn), and the like, but the present disclosure is not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN) or gallium nitride (GaN), but is not limited thereto.

The first electrode 134 is disposed on the first semiconductor layer 131. The first electrode 134 is an electrode which electrically connects the driving transistor DT and the first semiconductor layer 131. In this case, the first semiconductor layer 131 is a semiconductor layer doped with an n-type impurity and the first electrode 134 may be a cathode. The first electrode 134 may be disposed on a top surface of the first semiconductor layer 131 which is exposed from the emission layer 132 and the second semiconductor layer 133. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the second semiconductor layer 133. The second electrode 135 may be disposed on the top surface of the second semiconductor layer 133. The second electrode 135 is an electrode which electrically connects the high potential power line VL1 and the second semiconductor layer 133. In this case, the second semiconductor layer 133 is a semiconductor layer doped with a p-type impurity and the second electrode 135 may be an anode. The second electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation layer 136 which encloses or surrounds the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. In the encapsulation layer 136, contact holes which expose the first electrode 134 and the second electrode 135 are formed to electrically connect a second connection electrode CE2 and a first connection electrode CE1 to the first electrode 134 and the second electrode 135, respectively.

In the meantime, a part of the side surface of the first semiconductor layer 131 may be exposed from the encapsulation layer 136. The light emitting diode 130 manufactured on the wafer is separated from the wafer to be transferred onto the display panel PN. However, during the process of separating the light emitting diode 130 from the wafer, a part of the encapsulation layer 136 may be torn. For example, a part of the encapsulation layer 136 which is adjacent to a lower edge of the first semiconductor layer 131 of the light emitting diode 130 is torn during the process of separating the light emitting diode 130 from the wafer. Accordingly, a part of a lower side surface of the first semiconductor layer 131 may be exposed to the outside. However, even though the lower portion of the light emitting diode 130 is exposed from the encapsulation layer 136, the first connection electrode CE1 and the second connection electrode CE2 are formed after forming the second planarization layer 116b and the third planarization layer 116c which cover the side surface of the first semiconductor layer 131. Accordingly, a short problem (or a problem due to a short) may be reduced.

Next, the second planarization layer 116b and the third planarization layer 116c are disposed on the adhesive layer AD and the light emitting diode 130. The second planarization layer 116b overlaps a part of side surfaces of the plurality of light emitting diodes 130 to fix and protect the plurality of light emitting diodes 130. The third planarization layer 116c is formed to cover upper portions of the second planarization layer 116b and the light emitting diode 130, and contact holes which expose the first electrode 134 and the second electrode 135 of the light emitting diode 130 may be formed. The first electrode 134 and the second electrode 135 of the light emitting diode 130 are exposed from (or through the contact holes of) the third planarization layer 116c, and the third planarization layer 116c is partially disposed in an area between the first electrode 134 and the second electrode 135 to reduce a short problem (or to reduce a problem caused by a short). The second planarization layer 116b and the third planarization layer 116c may be configured by a single layer or a double layer, and for example, may be formed of photoresist or an acrylic organic material, but are not limited thereto.

In the meantime, the third planarization layer 116c may cover only the light emitting diode 130 and an area adjacent to the light emitting diode 130. The third planarization layer 116c may be disposed in an area of the sub pixel SP enclosed or surrounded by the bank BB and may be disposed in an island shape. Therefore, the bank BB may be disposed in a part of the top surface of the second planarization layer 116b and the third planarization layer 116c may be disposed in the other part of the top surface of the second planarization layer 116b.

The first connection electrode CE1 and the second connection electrode CE2 are disposed on the third planarization layer 116c. The first connection electrode CE1 is an electrode which electrically connects the second electrode 135 of the light emitting diode 130 and the high potential power line VL1. The first connection electrode CE1 may be electrically connected to the second electrode 135 of the light emitting diode 130 through a contact hole formed in the third planarization layer 116c.

The second connection electrode CE2 is an electrode which electrically connects the first electrode 134 of the light emitting diode 130 and the driving transistor DT. The second connection electrode CE2 may be connected to the 1-1-th reflection plate RF1a, the 1-2-th reflection plate RF1b, the third reflection plate RF3, and the fourth reflection plate RF4 of each of the plurality of sub pixels SP through contact holes formed in the third planarization layer 116c, the second planarization layer 116b, the adhesive layer AD, and the second passivation layer 115b. At this time, the 1-1-th reflection plate RF1a, the 1-2-th reflection plate RF1b, the third reflection plate RF3, and the fourth reflection plate RF4 are also connected to the source electrode SE of the driving transistor DT so that the source electrode SE of the driving transistor DT and the first electrode 134 of the light emitting diode 130 may be electrically connected to each other.

In the meantime, in the drawing, it is illustrated that the first electrode 134, the second connection electrode CE2, and the reflection plate RF are electrically connected to the source electrode SE of the driving transistor DT. However, the first electrode 134, the second connection electrode CE2, and the reflection plate RF may be connected to the drain electrode DE of the driving transistor DT, but they are not limited thereto.

A bank BB is disposed on the second planarization layer 116b exposed from (or through) the first connection electrode CE1 and the second connection electrode CE2, and the third planarization layer 116c. The bank BB may be disposed to be spaced apart from the light emitting diode 130 with a predetermined interval. For example, the bank BB may be disposed on the second planarization layer 116b with a predetermined interval from the light emitting diode 130 or may cover a part of the second connection electrode CE2 formed in the contact holes of the third planarization layer 116c and the second planarization layer 116b. The bank BB may be formed of an opaque material to reduce color mixture between the plurality of sub pixels SP and, for example, may be formed of black resin, but is not limited thereto.

A first protection layer 117 is disposed on the first connection electrode CE1, the second connection electrode CE2, and the bank BB. The first protection layer 117 is a layer for protecting components below the first protection layer 117, and may be configured by a single layer or a double layer of translucent epoxy, silicon oxide (SiOx) or silicon nitride (SiNx), but is not limited thereto.

A plurality of first pad electrodes PAD1 is disposed in a plurality of first pad areas PA1 and a plurality of second pad areas PA2 of the first substrate 110. Each of the plurality of first pad electrodes PAD1 may be configured by a plurality of conductive layers. For example, each of the plurality of first pad electrodes PAD1 includes a first conductive layer PE1a, a second conductive layer PE1b, and a third conductive layer PE1c.

First, the first conductive layer PE1a is disposed on the second interlayer insulating layer 114. The first conductive layer PE1a may be formed of the same conductive material as the source electrode SE and the drain electrode DE and for example, may be configured by (or may include) copper (Cu), aluminum (Al), molybdenum (Mo), nickel (Ni), titanium (Ti), chrome (Cr), or an alloy thereof, but is not limited thereto.

The first passivation layer 115a is disposed on the first conductive layer PE1a, and the second conductive layer PE1b is disposed on the first passivation layer 115a. The second conductive layer PE1b may be formed of the same conductive material as the reflection plate RF and, for example, may be configured by (or may include) silver (Ag), aluminum (Al), molybdenum (Mo), or an alloy thereof, but is not limited thereto.

The third conductive layer PE1c is disposed on the second conductive layer PE1b. The third conductive layer PE1c may be formed of the same conductive material as the first connection electrode CE1 and the second connection electrode CE2, and may include, for example, a transparent conductive material, such as indium tin oxide (ITO) or indium zinc oxide (IZO), but is not limited thereto.

At this time, even though it is not illustrated in the drawings, some of the plurality of conductive layers of the first pad electrode PAD1 are electrically connected to a plurality of wiring lines on the first substrate 110 to supply various signals to a plurality of wiring lines and a plurality of sub pixels SP (see, e.g., FIG. 3). For example, the first conductive layer PE1a and/or the second conductive layer PE1b of the first pad electrode PAD1 is connected to the data line DL, the high potential power line VL1, the low potential power line VL2, and the like disposed in the active area AA to transmit signals thereto.

A first metal layer ML1, a second metal layer ML2, and a plurality of insulating layers may be disposed together below the first pad electrode PAD1. The first metal layer ML1, the second metal layer ML2, and the plurality of insulating layers are disposed below the first pad electrode PAD1 to adjust a step of the first pad electrode PAD1. For example, the buffer layer 111, the gate insulating layer 112, the first metal layer ML1, the first interlayer insulating layer 113, and the second metal layer ML2 may be sequentially disposed between the first pad electrode PAD1 and the first substrate 110. The first metal layer ML1 may be formed of the same conductive material as the gate electrode GE and the second metal layer ML2 may be formed of the same conductive material as a 1-2-th capacitor electrode C1b. However, the plurality of insulating layers, the first metal layer ML1, and the second metal layer ML2 below the first pad electrode PAD1 may be omitted depending on a design and are not limited thereto.

A second substrate 120 is disposed below the first substrate 110. The second substrate 120 is a substrate which supports components disposed below the display device 100 and may be an insulating substrate. For example, the second substrate 120 may be formed of glass or resin. Further, the second substrate 120 may include polymer or plastic. The second substrate 120 may be formed of the same material as the first substrate 110. In some example embodiments, the second substrate 120 may be formed of a plastic material having flexibility.

A bonding layer BDL is disposed between the first substrate 110 and the second substrate 120. The bonding layer BDL may be formed of a material which is cured by various curing methods to bond the first substrate 110 and the second substrate 120. The bonding layer BDL may be disposed only in a partial area between the first substrate 110 and the second substrate 120 or may be disposed in the entire area therebetween.

A plurality of second pad electrodes PAD2 is disposed on a rear surface of the second substrate 120. The plurality of second pad electrodes PAD2 is electrodes which transmit signals from a driving component(s) disposed on the rear surface of the second substrate 120 to a plurality of side lines SRL, a plurality of first pad electrodes PAD1 and a plurality of wiring lines on the first substrate 110. The plurality of second pad electrodes PAD2 is disposed in an end portion of the second substrate 120 in the non-active area NA to be electrically connected to the side lines SRL which cover the end portion of the second substrate 120.

At this time, the plurality of second pad electrodes PAD2 may be also disposed so as to correspond to the plurality of pad areas PA1 and PA2. The plurality of first pad electrodes PAD1 may be disposed to correspond to the plurality of second pad electrodes PAD2, respectively, and then the first pad electrode PAD1 and the second pad electrode PAD2 which overlap each other may be electrically connected through the side line SRL.

Each of the plurality of second pad electrodes PAD2 includes a plurality of conductive layers. For example, each of the plurality of second pad electrodes PAD2 includes a fourth conductive layer PE2a, a fifth conductive layer PE2b, and a sixth conductive layer PE2c.

First, the fourth conductive layer PE2a is disposed below the second substrate. The fourth conductive layer PE2a may be configured by a conductive material such as copper (Cu), aluminum (Al), molybdenum (Mo), nickel (Ni), titanium (Ti), chrome (Cr), or an alloy thereof, but is not limited thereto.

The fifth conductive layer PE2b is disposed below the fourth conductive layer PE2a. The fifth conductive layer PE2b may be configured by a conductive material, such as copper (Cu), aluminum (Al), molybdenum (Mo), nickel (Ni), titanium (Ti), chrome (Cr), or an alloy thereof, but is not limited thereto.

The sixth conductive layer PE2c is disposed below the fifth conductive layer PE2b. The sixth conductive layer PE2c may be formed of a conductive material, for example, a transparent conductive material, such as indium tin oxide (ITO) or indium zinc oxide (IZO), but is not limited thereto.

A second protection layer 121 is disposed in the remaining area of the second substrate 120. The second protection layer 121 may protect various wiring lines and driving components formed on the second substrate 120. The second protection layer 121 may be configured by an organic insulating material, and for example, configured by benzocyclobutene or an acrylic organic insulating material, but is not limited thereto.

Even though it is not illustrated in the drawings, a driving component including a plurality of flexible films and a printed circuit board may be disposed on a rear surface of the second substrate 120. The plurality of flexible films is components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC may be disposed.

For example, the fourth conductive layer PE2a and/or the fifth conductive layer PE2b of the second pad electrode PAD2 extend to the plurality of flexible films disposed on the rear surface of the second substrate to be electrically connected to the plurality of flexible films. The plurality of flexible films may supply various signals to the plurality of side lines SRL, the plurality of first pad electrodes PAD1, the plurality of wiring lines, and the plurality of sub pixels SP through the second pad electrode PAD2. Therefore, the signal(s) from the driving component may be transmitted to the signal line(s) and the plurality of sub pixels SP on the front surface of the first substrate 110 through the plurality of second pad electrodes PAD2 of the second substrate 120, the side line SRL, and the plurality of first pad electrodes PAD1 of the first substrate 110.

Next, the plurality of side lines SRL is disposed on the side surfaces of the first substrate 110 and the second substrate 120. The plurality of side lines SRL may electrically connect the plurality of first pad electrodes PAD1 formed on the top surface of the first substrate 110 and the plurality of second pad electrodes PAD2 formed on the rear surface of the second substrate 120. The plurality of side lines SRL may be disposed so as to enclose or surround the side surface(s) of the display device 100. Each of the plurality of side lines SRL may cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL may be formed by a pad printing method using a conductive ink, for example, including silver (Ag), copper (Cu), molybdenum (Mo), chrome (Cr), and the like.

A side insulating layer 140 which covers the plurality of side lines SRL is disposed. The side insulating layer 140 may be formed on the top surface of the first substrate 110, the side surface(s) of the first substrate 110, the side surface(s) of the second substrate 120, and the rear surface of the second substrate 120 to cover the side lines SRL. The side insulating layer 140 may protect the plurality of side lines SRL.

In the meantime, when the plurality of side lines SRL is formed of a metal material, there may be a problem in that external light is reflected from the plurality of side lines SRL or light emitted from the light emitting diode 130 is reflected from the plurality of side lines SRL to be visibly recognized by the user. Therefore, the side insulating layer 140 is configured to include a black material to suppress reflection of the external light. For example, the side insulating layer 140 may be formed by a pad printing method using an insulating material including a black material, for example, a black ink.

A seal member 150 which covers the side insulating layer 140 is disposed. The seal member 150 is disposed so as to enclose or surround the side surface(s) of the display device 100 to protect the display device 100 from external impacts, moisture and oxygen, or the like. For example, the seal member 150 may be formed of polyimide (PI), poly urethane, epoxy, or acryl based insulating material, but is not limited thereto.

An optical film MF is disposed on the seal member 150, the side insulating layer 140, and the first protection layer 117. The optical film MF may be a functional film which implements a higher quality of images while protecting the display device 100. For example, the optical film MF may include an anti-scattering film, an anti-glare film, an anti-reflecting film, a low-reflecting film, an OLED transmittance controllable film, a polarizer, or the like, but is not limited thereto.

In the meantime, an edge of the seal member 150 and an edge of the optical film MF may be disposed on the same line. The optical film MF having a larger size is attached above the first substrate 110 during the manufacturing process of the display device 100 and the seal member which covers the side insulating layer 140 may be formed. Thereafter, laser is irradiated on the seal member 150 and the optical film MF so as to correspond to an edge of the display device 100 to cut a part of the seal member and the optical film MF. Accordingly, the size of the display device 100 is adjusted by an outer periphery cutting process of the seal member 150 and the optical film MF and the edge of the display device 100 may be formed to be flat.

Hereinafter, a manufacturing method of a display device according to one or more example embodiments of the present disclosure is described.

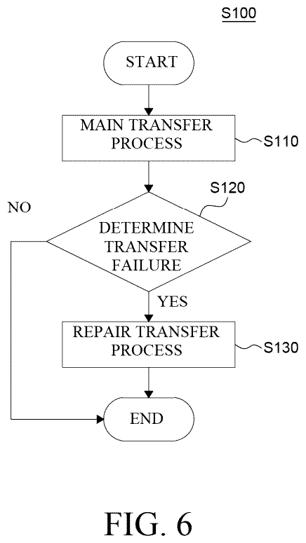

FIG. 6 is a process flowchart for describing a manufacturing method of a display device according to one or more example embodiments of the present disclosure.

Referring to FIG. 6, a manufacturing method S100 of a display device according to one or more example embodiments of the present disclosure includes a main transfer process step S110, a transfer failure determining step S120, and a repair transfer process step S130.

In the main transfer process step S110, a plurality of light emitting diodes may be transferred onto a display panel using a main alignment key disposed on a wafer.

Specifically, in the main transfer process step S110, a primary transfer process is performed to transfer the plurality of light emitting diodes on the wafer onto a donor substrate and a secondary transfer process is performed to transfer the plurality of light emitting diodes on the donor substrate onto a display panel.

In the transfer failure determining step S120, a defective light emitting diode which is missed (or absent) or misplaced from the transferring position in the main transfer process step S110 is determined.

Specifically, in the transfer failure determining step S120, when there is no defective light emitting diode which is missed or misplaced from the transferring position in the main transfer process step S110, it is determined that all the light emitting diodes are transferred onto the display panel to finish the manufacturing process of the display device.

In contrast, when in the transfer failure determining step S120, there is a defective light emitting diode which is missed or misplaced from the transferring position in the main transfer process step S110, a position of the defective transferring area corresponding to the defective light emitting diode which is missed or misplaced from the transferring position is determined.

In the repair transfer process step S130, at least one light emitting diode corresponding to the defective transferring area may be transferred onto the display panel using a repair alignment key AK2c disposed on the wafer.

Specifically, in the repair transfer process step S130, a primary transfer process is performed to transfer at least one light emitting diode corresponding to a defective transferring area on the wafer onto a donor substrate and a secondary transfer process is performed to transfer at least one light emitting diode corresponding to the defective transferring area on the donor substrate onto the display panel.

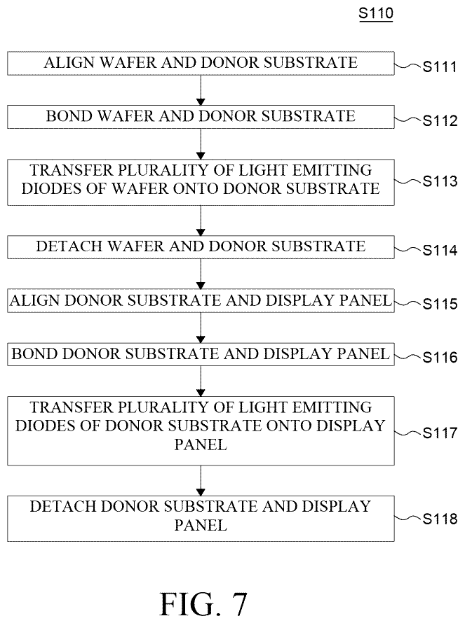

Hereinafter, a main transfer process S110 is described with reference to FIGS. 7 to 14.

FIG. 7 is a process flowchart for describing a main transfer process of a manufacturing method of a display device according to one or more example embodiments of the present disclosure.

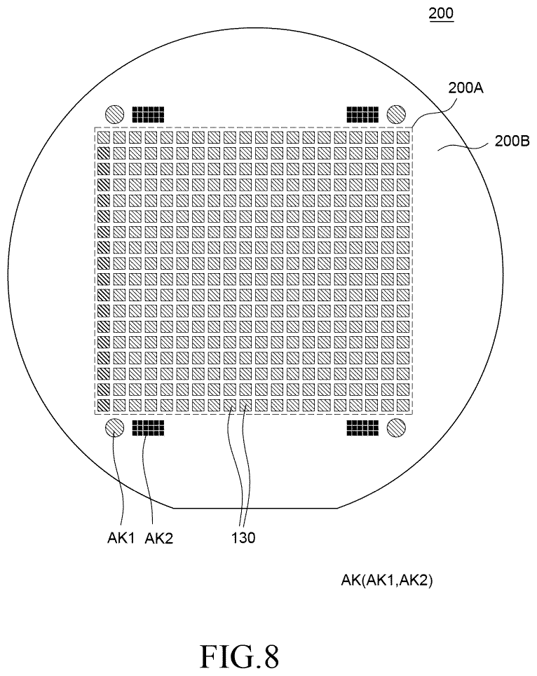

FIG. 8 is a view illustrating a wafer used for a manufacturing method of a display device according to one or more example embodiments of the present disclosure.

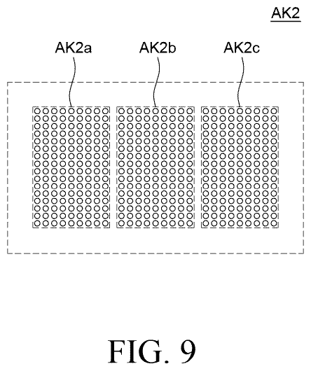

FIG. 9 is a view illustrating a second alignment key disposed on a wafer used for a manufacturing method of a display device according to one or more example embodiments of the present disclosure.

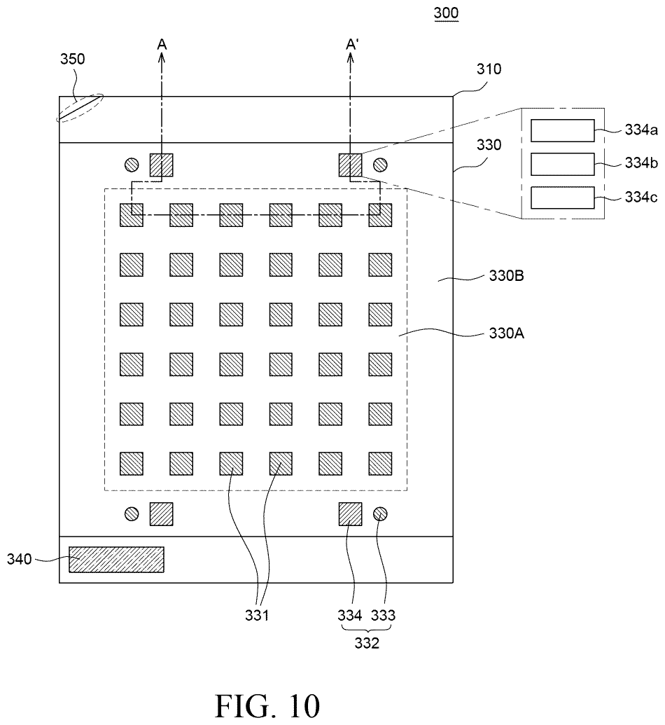

FIG. 10 is a view illustrating a donor used for a manufacturing method of a display device according to one or more example embodiments of the present disclosure.

Referring to FIG. 7, the main transfer process step S110 may include a step S111 of aligning a wafer and a donor substrate, a step S112 of bonding the wafer and the donor substrate, a step S113 of transferring a plurality of light emitting diodes disposed on the wafer onto the donor substrate, a step S114 of detaching the wafer and the donor substrate, a step S115 of aligning the donor substrate and the display panel, a step S116 of bonding the donor substrate on which the plurality of light emitting diodes is disposed and the display panel, a step S117 of transferring the plurality of light emitting diodes disposed on the donor substrate onto the display panel, and a step S118 of detaching the display panel and the donor substrate.

Referring to FIGS. 8 to 10, the above-described wafer 200 is a substrate on which the plurality of light emitting diodes 130 is formed. A crystal layer is grown by forming a material, such as gallium nitride (GaN) or indium gallium nitride (InGaN), which configures the plurality of light emitting diodes 130 on the wafer 200, the crystal layer is cut into individual chips and an electrode is formed to form the plurality of light emitting diodes 130. The wafer 200 may be formed of sapphire, silicon carbide (SiC), gallium nitride (GaN), zinc oxide (ZnO), or the like, but is not limited thereto.

At this time, a plurality of light emitting diodes 130 which emits light with the same color may be formed or a plurality of light emitting diodes 130 which emits light with different colors may be formed, on one wafer 200. Hereinafter, the description is made by assuming that the plurality of light emitting diodes 130 which emits light with the same color is formed on one wafer 200.

The wafer 200 includes an active area 200A and an outer peripheral area 200B. In the active area 200A, the plurality of light emitting diodes 130 is formed and in the outer peripheral area 200B which is disposed at the outside of the active area 200A, a plurality of alignment keys AK is disposed.

The plurality of alignment keys AK includes a first alignment key AK1 and a second alignment key AK2. The first alignment key AK1 and the second alignment key AK2 may be disposed in the vicinity of a corner of the wafer 200 in the outer peripheral area 200B. However, the first alignment key AK1 and the second alignment key AK2 may be disposed in a position other than the corner of the wafer 200 depending on the design, and the number of first alignment keys AK1 and second alignment keys AK2 may be also designed in various ways.

The first alignment key AK1 is a component used to align the wafer 200 and the donor substrate 300. The first alignment key AK1 is a mark for adjusting an alignment and parallelism with the donor substrate 300 when the plurality of light emitting diodes 130 of the wafer 200 is transferred onto the donor substrate 300. For example, a first alignment key AK1 of the wafer 200 and a first alignment bump 333 of the donor substrate 300 are aligned to adjust the alignment and the parallelism of the wafer 200 and the donor substrate 300.

The second alignment key AK2 is a component used to align the donor substrate 300 and the display panel PN. When the plurality of light emitting diodes 130 of the wafer 200 is transferred onto the donor substrate 300, the second alignment key AK2 may be transferred onto the donor substrate 300 together with the plurality of light emitting diodes 130. Thereafter, the alignment and the parallelism of the donor substrate 300 and the display panel PN may be adjusted using the second alignment key AK2 on the donor substrate 300.

Specifically, the second alignment key AK2 may include a plurality of main alignment keys AK2a and AK2b and a repair alignment key AK2c.

The plurality of main alignment keys AK2a and AK2b are second alignment keys used to adjust the alignment and the parallelism of the donor substrate 300 and the display panel PN in the main transfer process S110. The plurality of main alignment keys AK2a and AK2b may be configured by a first main alignment key AK2a and a second main alignment key AK2b. At this time, a plurality of first main alignment keys AK2a and a plurality of second main alignment keys AK2b may be configured, respectively.

The repair alignment key AK2c is the second alignment key used to adjust the alignment and the parallelism of the donor substrate 300 and the display panel PN in the main transfer process S110. Further, a plurality of repair alignment keys AK2c may be configured.

The first alignment key AK1 and the second alignment key AK2 may be formed together with the plurality of light emitting didoes 130 or formed by a separate process from the plurality of light emitting diodes 130. If the first alignment key AK1 and the second alignment key AK2 are formed together with the plurality of light emitting didoes 130, the first alignment key AK1 and the second alignment key AK2 may be formed with the same material as at least a part of a material forming the plurality of light emitting didoes 130. However, the material and the forming process of the first alignment key AK1 and the second alignment key AK2 may be configured in various forms depending on the design, but are not limited thereto.

Shapes and sizes of the first alignment key AK1 and the second alignment key AK2 may be configured in various forms. In order to identify the first alignment key AK1 and the second alignment key AK2 disposed in the outer peripheral area 200B, the first alignment key AK1 and the second alignment key AK2 may have different shapes or sizes. For example, the first alignment key AK1 may be larger than the second alignment key AK2, but is not limited thereto.

Referring to FIG. 10, the donor substrate 300 includes a base layer 310, an adhesive layer 320, a resin layer 330, a plurality of bumps 331, and a plurality of alignment bumps 332.

The base layer 310 is configured to support various compositions included in the donor substrate 300 and may be formed of a material more rigid than at least the resin layer 330 to minimize the bending of the resin layer 330. The base layer 310 is disposed below the resin layer 330 to support the resin layer 330, the plurality of bumps 331, and the plurality of alignment bumps 332. For example, the base layer 310 may include polymer, plastic, or the like or may be also formed of poly carbonate (PC), polyethylene terephthalate (PET), or the like, but is not limited thereto.

In the meantime, an identification pattern and a direction pattern may be disposed in a part of the base layer 310 which protrudes to the outside of the resin layer 330.

The identification pattern 340 is a pattern which is formed on the base layer 310 to identify the donor substrate 300. The plurality of donor substrates 300 may be managed using a unique identification pattern 340 assigned to every donor substrate 300. The identification pattern 340 may be disposed on a top surface, a rear surface, or the like of the base layer 310 and may be formed by a printing method or a laser engraving method. For example, the identification pattern 340 may be an identification (ID) or a barcode configured with numbers or characters, but is not limited thereto. In the meantime, even though in FIG. 10, it is illustrated that one identification pattern 340 is formed at a left lower end of the donor substrate 300, the number and the placement of the identification pattern are not limited thereto.

The direction pattern 350 is a pattern which is formed on the base layer 310 to distinguish a direction of the donor substrate 300. For example, when the donor substrate 300 is inserted into process equipment, if the donor substrate 300 is reversely inserted, the light emitting diode 130 may be transferred in a different place from a designed position or a defect may occur. Accordingly, in order to distinguish the direction of the donor substrate 300, the direction pattern 350 may be disposed in any one place of the base layer 310. The direction pattern 350 may be formed by a printing method, a laser engraving method, or the like, or may be formed by chamfering a corner of the base layer 310, but is not limited thereto.

The resin layer 330 is disposed on the base layer 310. The resin layer 330 may support the plurality of bumps 331 to which the plurality of light emitting diodes 130 is attached, during the transfer process. The resin layer 330 may be formed by a polymer resin having viscoelasticity, for example, the resin layer 330 may be configured by poly dimethyl siloxane (PDMS), poly urethane acrylate (PUA), polyethylene glycol (PEG), polymethylmethacrylate (PMMA), polystyrene (PS), epoxy resin, urethane resin, acrylic resin, or the like. However, it is not limited thereto.

The resin layer 330 includes a transferring area 330A and a non-transferring area 330B.

The transferring area 330A is an area in which the plurality of bumps 331 is disposed. The transferring area 330A is an area in which the plurality of bumps 331 to be attached with the plurality of light emitting diodes 130 is disposed and may be disposed so as to overlap at least a part of the wafer 200 or the display panel PN during the transfer process.

The non-transferring area 330B is an area in which the plurality of alignment bumps 332 is disposed. The plurality of light emitting diodes 130 is not transferred in the non-transferring area 330B from the wafer 200, and the second alignment key AK2 of the wafer 200 may be transferred in the non-transferring area.

The plurality of bumps 331 is bumps in which the plurality of light emitting diodes 130 is disposed and may be formed extending from one surface of the resin layer 330. The plurality of bumps 331 may be integrally formed with the resin layer 330 and may be formed of a polymer material having viscoelasticity, which is the same as the resin layer 330. For example, the plurality of bumps 331 may be formed of poly dimethyl siloxane (PDMS), poly urethane acrylate (PUA), polyethylene glycol (PEG), polymethylmethacrylate (PMMS), polystyrene (PS), epoxy resin, urethane resin, acrylic resin, or the like, but is not limited thereto.

The plurality of light emitting diodes 130 may be temporarily attached onto top surfaces of the plurality of bumps 331. The plurality of light emitting diodes 130 which is formed on the wafer 200 may be transferred onto the top surfaces of the plurality of bumps 331. The plurality of light emitting diodes 130 may temporarily maintain a state being attached onto the top surfaces of the plurality of bumps 331 before being transferred onto the display panel PN.

At this time, the plurality of bumps 331 may be disposed with the same interval as the interval of the plurality of sub pixels. For example, when the plurality of light emitting diodes 130 is transferred onto the display panel PN, the plurality of light emitting diodes 130 is transferred so as to correspond to the plurality of sub pixels, respectively. If the plurality of light emitting diodes 130 which is transferred onto the donor substrate 300 is transferred in one time, only when the plurality of light emitting diodes 130 on the donor substrate 300 is disposed so as to correspond to the plurality of sub pixels, respectively, the plurality of light emitting diodes 130 which is transferred onto the display panel PN in one time may be transferred so as to correspond to the plurality of sub pixels. However, the placement and the interval of the plurality of bumps 331 may vary depending on a design, and are not limited thereto.

Sizes of the plurality of bumps 331 may be larger than the sizes of the plurality of light emitting diodes 130. Sizes of the top surfaces of the plurality of bumps 331 are formed to be larger than the sizes of the plurality of light emitting diodes 130 so that even though an alignment error of the donor substrate 300 and the wafer 200 is generated, the plurality of light emitting diodes 130 may be seated on the plurality of bumps 331. Accordingly, the sizes of the top surfaces of the plurality of bumps 331 may be formed to be larger than the sizes of the plurality of light emitting diodes 130 in consideration of the alignment error of the wafer 200 and the donor substrate 300.

The plurality of alignment bumps 332 is disposed in the non-transferring area 330B. The plurality of alignment bumps 332 includes a plurality of first alignment bumps 333 and a plurality of second alignment bumps 334.

The plurality of first alignment bumps 333 is components used to align the wafer 200 and the donor substrate 300. The plurality of first alignment bumps 333 may be disposed so as to correspond to the first alignment key AK1 of the wafer 200. For example, the first alignment key AK1 of the wafer 200 and the first alignment bump 333 of the donor substrate 300 are aligned to adjust the alignment and the parallelism of the wafer 200 and the donor substrate 300. At this time, the first alignment bumps 333 and the first alignment key AK1 may have different shapes or sizes to be easily identified. For example, one of the first alignment bumps 333 and the first alignment key AK1 may have a donut shape with a hole in the center and the other one may be formed to have a circular shape overlapping the hole. In FIG. 10, it is illustrated that the first alignment key AK1 of the wafer 200 and the first alignment bump 333 of the donor substrate 300 have a circular shape, but the shapes of the first alignment key AK1 and the first alignment bump 333 are not limited thereto.

The second alignment bump 334 may be disposed so as to correspond to the second alignment key AK2 of the wafer 200. For example, the first alignment key AK1 of the wafer 200 and the first alignment bump 333 of the donor substrate 300 are aligned to align the wafer 200 and the donor substrate 300. Thereafter, the plurality of light emitting diodes 130 of the wafer 200 may be transferred onto the plurality of bumps 331 of the donor substrate 300, and the second alignment key AK2 of the wafer 200 may be transferred onto the second alignment bump 334 of the donor substrate 300. At this time, the second alignment key AK2 which is transferred onto the donor substrate 300 may be used to align the display panel PN and the donor substrate 300 thereafter.

Specifically, a plurality of main alignment areas 334a and 334b and a repair alignment area 334c are provided on the second alignment bump 334.

A plurality of main alignment areas 334a and 334b are areas onto which the plurality of main alignment keys AK2a and AK2b is transferred in the main transfer process S110. A repair alignment area 334c is an area onto which the repair alignment key AK2c is transferred in the main transfer process S110.

Specifically, the plurality of main alignment areas 334a and 334b may be configured by a first main alignment area 334a and a second main alignment area 334b, the first main alignment key AK2a may be transferred onto the first main alignment area 334a, and the second alignment key AK2b may be transferred onto the second main alignment area 334b.

In the meantime, even though it is not illustrated in the drawing, a plurality of bumps may be further disposed in the non-transferring area 330B in addition to the plurality of alignment bumps 332. Specifically, during the transfer process, in order to minimize the deformation of the resin layer 330 and the plurality of bumps 331 of the transferring area 330A due to the impact applied to the donor substrate 300, a plurality of bumps may be further disposed in the non-transferring area 330B. For example, after bonding the wafer 200 and the donor substrate 300, when the plurality of light emitting diodes 130 is transferred onto the donor substrate 300, the plurality of light emitting diodes 130 moves onto the donor substrate 300 to apply the impact to the donor substrate 300. When the impact is applied to the donor substrate 300, the positions or the shapes of the resin layer 330 and the plurality of bumps 331 of the transferring area 330A may be modified. At this time, the deformation of the resin layer 330 and the plurality of bumps 331 of the transferring area 330A may be minimized while maintaining a bonded state of plurality of bumps of the non-transferring area 330B which is disposed to enclose or surround the transferring area 330A, and the wafer.

In one or more example embodiments, the plurality of bumps 331 is not disposed on the donor substrate 300, and the plurality of light emitting diodes 130 may be directly transferred onto the resin layer 330. That is, the donor substrate 300 may not include a separate bump 331. A structure of the donor substrate 300 may vary depending on a shape, a placement, and a transferring method of the plurality of light emitting diodes 130, but is not limited thereto. Hereinafter, for the convenience of description, it is assumed that the donor substrate 300 includes a plurality of bumps 331 and the plurality of light emitting diodes 130 is transferred onto the plurality of bumps 331, respectively.

An adhesive layer 320 is disposed between the resin layer 330 and the base layer 310. The adhesive layer 320 bonds the resin layer 330 and the display panel PN. The adhesive layer 320 may be formed of a material having adhesiveness and, for example, may be formed of an optically clear adhesive (OCA), a pressure sensitive adhesive (PSA) or the like, but is not limited thereto.

However, in one or more other example embodiments, the adhesive layer 320 may be omitted depending on the design. For example, the resin layer 330 may be formed by immediately coating a material which forms the resin layer 330 on the base layer 310 and then curing the material. In this case, even though the adhesive layer 320 is not disposed, the resin layer 330 may be attached onto the base layer 310 so that the adhesive layer 320 may be omitted depending on the design, but is not limited thereto.

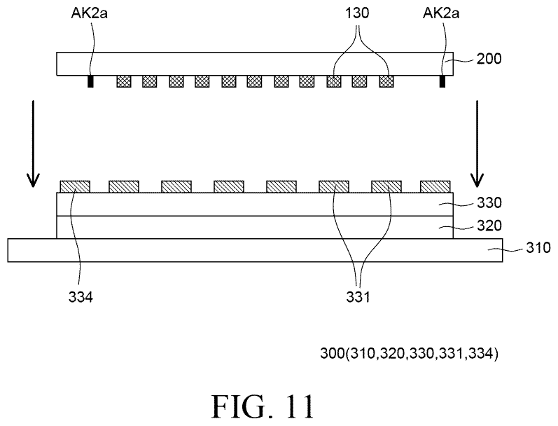

FIG. 11 is a cross-sectional view for describing a step of bonding a wafer and a donor substrate in a main transfer process of a manufacturing method of a display device according to one or more example embodiments of the present disclosure.

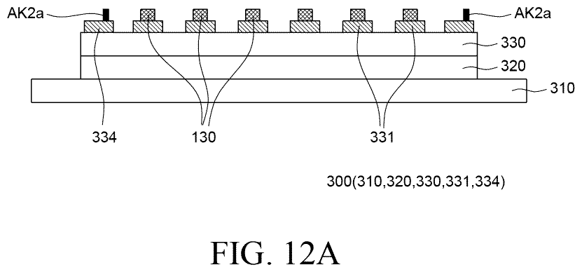

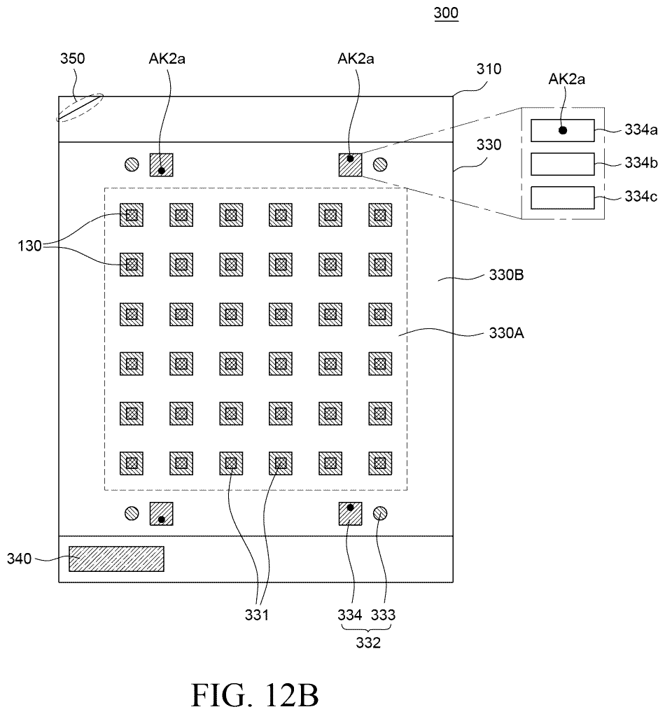

FIG. 12A is a cross-sectional view for describing a step of transferring a plurality of light emitting diodes of a wafer onto a donor substrate in a main transfer process of a manufacturing method of a display device according to one or more example embodiments of the present disclosure.

FIG. 12B is a front view for describing a step of transferring a plurality of light emitting diodes of a wafer onto a donor substrate in a main transfer process of a manufacturing method of a display device according to one or more example embodiments of the present disclosure.

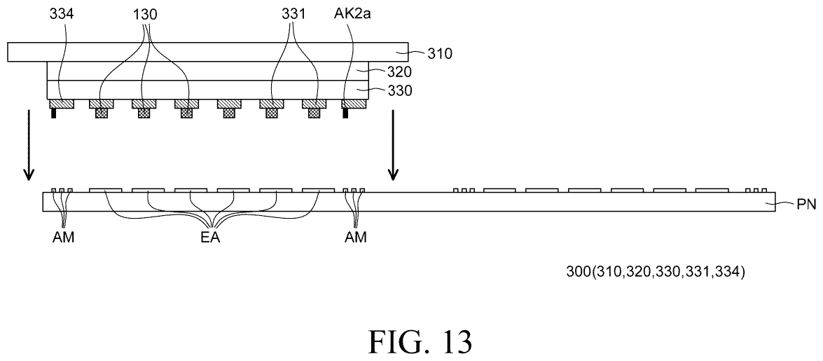

FIG. 13 is a cross-sectional view for describing a step of bonding a donor substrate and a display panel in a main transfer process of a manufacturing method of a display device according to one or more example embodiments of the present disclosure.

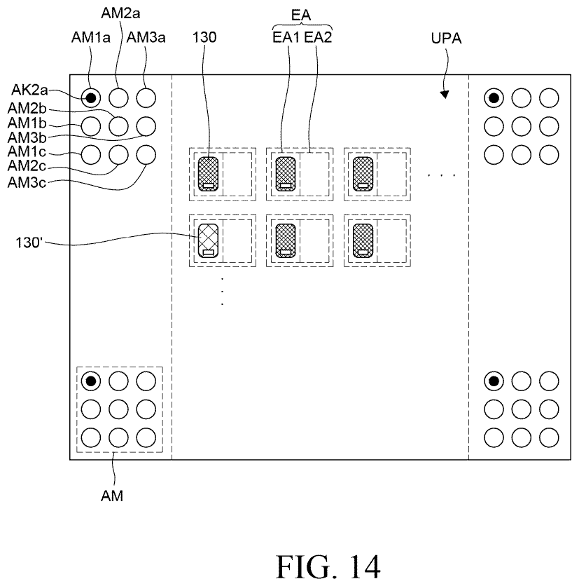

FIG. 14 is a front view for describing a step of transferring a plurality of light emitting diodes of a donor substrate onto a display panel in a main transfer process of a manufacturing method of a display device according to one or more example embodiments of the present disclosure.

Specifically, FIGS. 11 and 12A correspond to a cross-sectional view taken along the line A-A′ of FIG. 10.

In the step S111 of aligning the wafer and the donor substrate, the wafer 200 on which the plurality of light emitting diodes 130 is formed and the donor substrate 300 are inserted into process equipment, and the wafer 200 and the donor substrate 300 which are inserted into the process equipment are aligned. In a state in which the wafer 200 and the donor substrate 300 are disposed such that the plurality of light emitting diodes 130 on the wafer 200 and the plurality of bumps 331 of the donor substrate 300 are opposite to each other, the wafer 200 and the donor substrate 300 may be aligned. Specifically, a center of the first alignment key AK1 of the wafer 200 and a center of the first alignment bump 333 of the donor substrate 300 are aligned to align the wafer 200 and the donor substrate 300.

Referring to FIG. 11, next, in the step S112 of bonding the wafer and the donor substrate, the wafer 200 and the donor substrate 300 are bonded while maintaining a state in which alignment of the wafer 200 and the donor substrate 300 is completed.

Thereafter, in the step S113 of transferring the plurality of light emitting diodes disposed on the wafer onto the donor substrate, in a state in which the wafer 200 and the donor substrate 300 are bonded to be opposite to each other, laser may be selectively irradiated onto only one or more light emitting diodes 130 to be transferred onto the donor substrate 300, among the plurality of light emitting diodes 130. The laser-irradiated one or more light emitting diodes 130 are detached from the wafer 200 to be transferred onto the plurality of bumps 331 of the donor substrate 300.

At this time, a plurality of main alignment keys AK2a and AK2b among the plurality of second alignment keys AK2 of the wafer 200 may be also transferred onto the donor substrate 300. In a state in which the wafer 200 and the donor substrate 300 are bonded to be opposite to each other, laser may be selectively irradiated only on some main alignment keys to be transferred onto the donor substrate 300, among the plurality of main alignment keys AK2a and AK2b. The laser-irradiated main alignment key(s) is/are detached from the wafer 200 to be transferred onto the main alignment areas 334a and 334b of the second alignment bump 334 of the donor substrate 300.

For example, referring to FIGS. 12A and 12B, the first main alignment keys AK2a of the wafer 200 may be transferred onto the first main alignment area 334a of the second alignment bump 334 of the donor substrate 300.

Alternatively, even though it is not illustrated, the second main alignment key AK2b of the wafer 200 may be transferred onto the second main alignment area 334b of the second alignment bump 334 of the donor substrate.

That is, in some aspects, only any one of the first main alignment key AK2a and the second main alignment key AK2b may be transferred onto the donor substrate 300. In other aspects, both the first main alignment key AK2a and the second main alignment key AK2b may be transferred onto the donor substrate 300.

Thereafter, in the step S114 of detaching the wafer and the donor substrate, the wafer 200 and the donor substrate 300 are detached from each other, and the donor substrate 300 onto which the light emitting diode 130 is transferred is discharged from the process equipment.

Next, referring to FIGS. 13 and 14, in the step S115 of aligning the donor substrate and the display panel, the donor substrate 300 on which the plurality of light emitting diodes 130 is disposed and the display panel PN are inserted into the process equipment, and the donor substrate 300 and the display panel PN are aligned.

The above-described display panel PN is a display panel PN in which a circuit for driving the plurality of light emitting diodes 130, for example, the driving transistor DT and the plurality of wiring lines are completely formed. That is, in the display panel PN, an electrode area EA which is electrically connected to the driving transistor DT and the plurality of wiring lines may be formed. The electrode area EA may be divided into a first electrode area EA1 and a second electrode area EA2. The first electrode area EA1 is an area onto which the plurality of light emitting diodes 130 is transferred by the main transfer process S110 and the second electrode area EA2 is an area onto which the plurality of light emitting diodes 130 is transferred by the repair transfer process S130.

In the meantime, the alignment mark AM of the display panel may include a plurality of main alignment marks AM1a, AM2a, AM1b, AM2b, AM1c, and AM2c and repair alignment marks AM3a, AM3b, and AM3c.

The plurality of main alignment marks AM1a, AM2a, AM1b, AM2b, AM1c, and AM2c may match the plurality of main alignment keys AK2a and AK2b. That is, the first main alignment marks AM1a, AM1b, and AM1c may match the first main alignment key AK2a, and the second main alignment marks AM2a, AM2b, and AM2c may match the second main alignment key AK2b.

A plurality of first main alignment marks AM1a, AM1b, and AM1c may be configured. For example, the first main alignment marks AM1a, AM1b, and AM1c may include a first alignment mark AM1a for a red light emitting diode, a first alignment mark AM1b for a green light emitting diode, and a first alignment mark AM1c for a blue light emitting diode.

Further, a plurality of second main alignment marks AM2a, AM2b, and AM2c may be configured. For example, the second main alignment marks AM2a, AM2b, and AM2c may include a second alignment mark AM2a for a red light emitting diode, a second alignment mark AM2b for a green light emitting diode, and a second alignment mark AM2c for a blue light emitting diode.

At this time, the donor substrate 300 and the display panel PN may be aligned based on the plurality of main alignment keys AK2a and AK2b of the donor substrate 300 and the plurality of main alignment marks AM1a, AM2a, AM1b, AM2b, AM1c, and AM2c of the display panel PN.

For example, the donor substrate 300 and the display panel PN may be aligned by overlapping the first main alignment key AK2a of the donor substrate 300 and the first main alignment marks AM1a, AM1b, and AM1c of the display panel PN. Alternatively, the donor substrate and the display panel may be aligned by overlapping the second main alignment key AK2b of the donor substrate 300 and the second main alignment marks AM2a, AM2b, and AM2c of the display panel PN.

Therefore, the plurality of light emitting diodes 130 and the electrode area EA of the display panel PN may overlap. To be more specific, the plurality of light emitting diodes 130 and a first electrode area EA1 of the electrode area EA of the display panel PN may overlap.

In the step S116 of bonding the donor substrate on which the plurality of light emitting diodes is disposed and the display panel, the display panel PN and the donor substrate 300 are bonded while maintaining a state in which alignment of the display panel PN and the donor substrate 300 is completed.

Thereafter, in the step S117 of transferring the plurality of light emitting diodes disposed on the donor substrate onto the display panel, in a state in which the display panel PN and the donor substrate 300 are bonded to be opposite to each other, laser may be selectively irradiated onto only one or more light emitting diodes 130 to be transferred onto the display panel PN, among the plurality of light emitting diodes 130. The laser-irradiated one or more light emitting diode 130 are detached from the donor substrate 300 to be transferred onto the first electrode area EA1 of the display panel PN.

At this time, the main alignment keys AK2a and AK2b among the plurality of second alignment keys AK2 of the donor substrate 300 may be also transferred onto the display panel PN. In a state in which the donor substrate 300 and the display panel PN are bonded to be opposite to each other, laser may be selectively irradiated only on some main alignment keys to be transferred onto the display panel PN, among the plurality of main alignment keys AK2a and AK2b. The laser-irradiated main alignment key(s) is/are detached from the donor substrate 300 to be transferred onto any one or more of the plurality of main alignment marks AM1a, AM2a, AM1b, AM2b, AM1c, and AM2c of the display panel PN.

For example, the first main alignment key AK2a of the donor substrate 300 may be transferred onto the first main alignment marks AM1a, AM1b, and AM1c of the display panel PN. To be more specific, referring to FIGS. 13 and 14, when it is assumed that the plurality of light emitting diodes 130 is red light emitting diodes, the first main alignment key AK2a may be transferred onto the first main alignment mark AM1a for the red light emitting diode.

Alternatively, even though it is not illustrated in the drawing, the second main alignment key AK2b of the donor substrate 300 may be transferred onto the second main alignment marks AM2a, AM2b, and AM2c of the display panel PN.

That is, in some aspects, only any one of the first main alignment key AK2a and the second main alignment key AK2b may be transferred onto the display panel PN. In other aspects, both the first main alignment key AK2a and the second main alignment key AK2b may be transferred onto the display panel PN.

Thereafter, in the step S118 of detaching the display panel and the donor substrate, the display panel PN and the donor substrate 300 are detached and the donor substrate 300 onto which the light emitting diode 130 is transferred is discharged from the process equipment.

Accordingly, the main transfer process S110 may be completed by primarily transferring the plurality of light emitting diodes 130 from the wafer 200 to the donor substrate 300 and secondarily transferring the plurality of light emitting diodes 130 transferred onto the donor substrate 300 onto the display panel PN.

In the transfer failure determining step S120, a defective light emitting diode 130′ which is missed or misplaced from the transferring position in the main transfer process step S110 is determined.

Specifically, in the transfer failure determining step S120, when there is no defective light emitting diode which is missed or misplaced from the transferring position in the main transfer process step S110, it is determined that all the light emitting diodes 130 are transferred onto the display panel PN to finish the manufacturing process of the display device.

In contrast, when in the transfer failure determining step S120, there is a defective light emitting diode 130′ which is missed or misplaced from the transferring position in the main transfer process step S110, a position of the defective transferring area corresponding to the defective light emitting diode 130′ which is missed or misplaced from the transferring position is determined.

That is, as illustrated in FIG. 14, a defective light emitting diode 130′ may be disposed in the first electrode area EA1 among electrode areas EA disposed in a second row and first column. That is, the electrode area EA disposed in the second row and first column in which the defective light emitting diode 130′ is disposed may be determined as a defective transferring area.

Therefore, in the display device according to one or more example embodiments of the present disclosure, in order to repair a sub pixel in which the defective light emitting diode 130′ is formed, the repair transfer process step S130 may be performed.

That is, in the repair transfer process step S130, at least one light emitting diode for repairing the defective light emitting diode 130′ may be transferred onto the display panel PN using a repair alignment key AK2c disposed on the wafer 200.

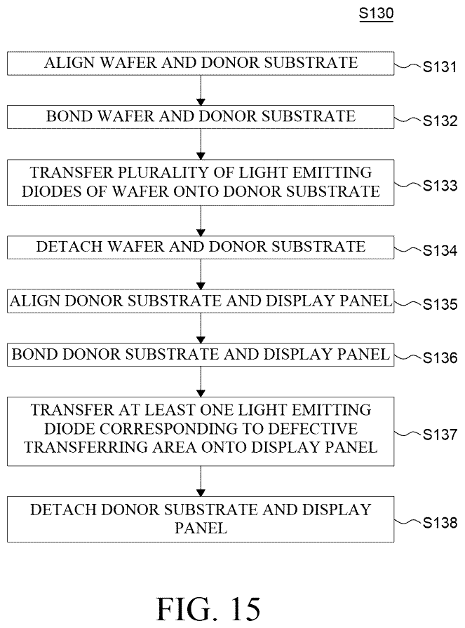

Hereinafter, a repair transfer process S130 is described with reference to FIGS. 15 to 19. For the convenience of description, description is made below with reference to reference numerals used in FIGS. 1 to 14.

FIG. 15 is a process flowchart for describing a repair transfer process of a manufacturing method of a display device according to one or more example embodiments of the present disclosure.

Referring to FIG. 15, the repair transfer process step S130 may include a step S131 of aligning a wafer and a donor substrate, a step S132 of bonding the wafer and the donor substrate, a step S133 of transferring a plurality of light emitting diodes disposed on the wafer onto the donor substrate, a step S134 of detaching the wafer and the donor substrate from each other, a step S135 of aligning the donor substrate and the display panel, a step S136 of bonding the donor substrate on which at least one light emitting diode is disposed and the display panel, a step S137 of transferring at least one light emitting diode corresponding to a defective transferring area onto the display panel, and a step S138 of detaching the display panel and the donor substrate from each other.

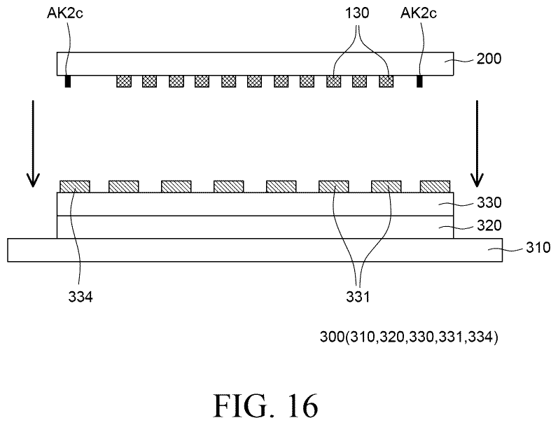

FIG. 16 is a cross-sectional view for describing a step of bonding a wafer and a donor substrate in a repair transfer process of a manufacturing method of a display device according to one or more example embodiments of the present disclosure.

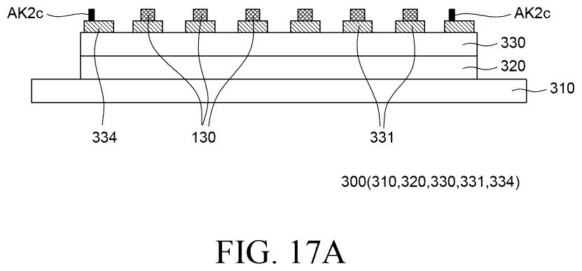

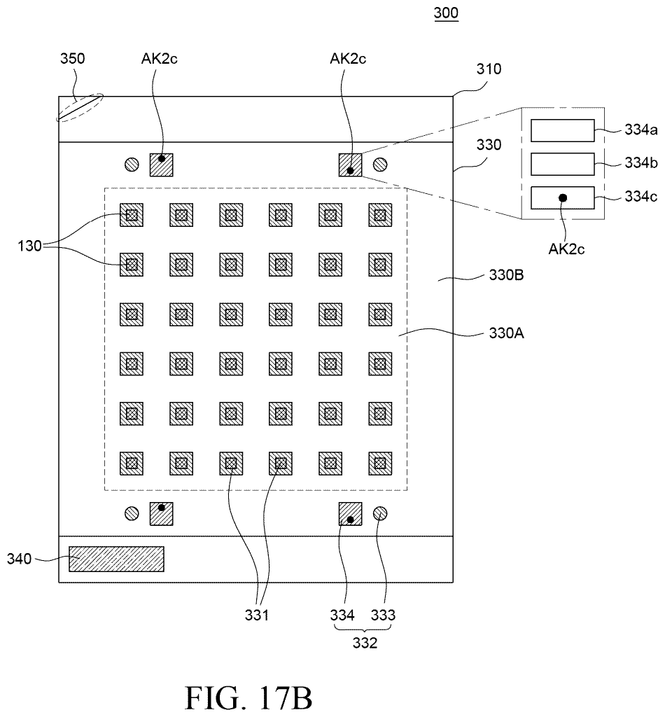

FIG. 17A is a cross-sectional view for describing a step of transferring at least one light emitting diode of a wafer onto a donor substrate in a repair transfer process of a manufacturing method of a display device according to one or more example embodiments of the present disclosure.

FIG. 17B is a front view for describing a step of transferring a plurality of light emitting diodes of a wafer onto a donor substrate in a repair transfer process of a manufacturing method of a display device according to one or more example embodiments of the present disclosure.

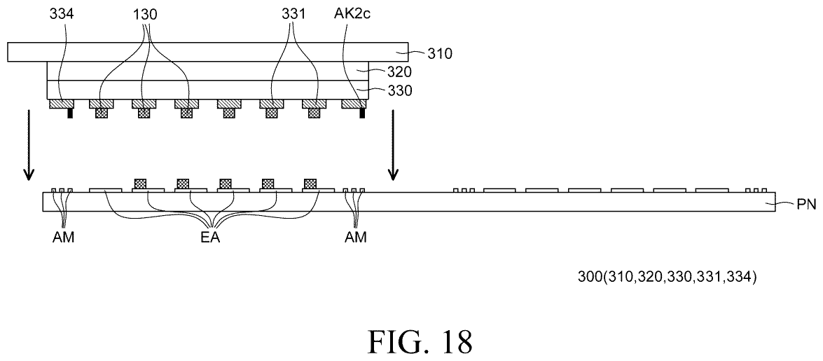

FIG. 18 is a cross-sectional view for describing a step of bonding a donor substrate and a display panel in a repair transfer process of a manufacturing method of a display device according to one or more example embodiments of the present disclosure.

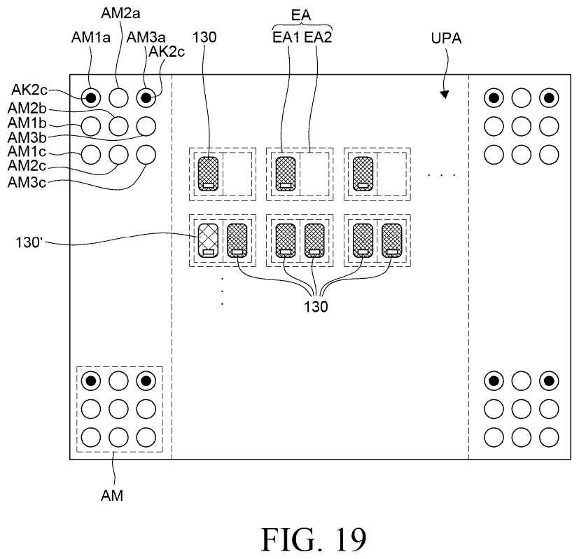

FIG. 19 is a front view for describing a step of transferring a plurality of light emitting diodes of a donor substrate onto a display panel in a repair transfer process of a manufacturing method of a display device according to one or more example embodiments of the present disclosure.

Specifically, FIGS. 16 and 17A correspond to a cross-sectional view taken along the line A-A′ of FIG. 10.

In the step S131 of aligning the wafer and the donor substrate, the wafer 200 on which the plurality of light emitting diodes 130 is formed and the donor substrate 300 are inserted into process equipment, and the wafer 200 and the donor substrate 300 which are inserted into the process equipment are aligned. In a state in which the wafer 200 and the donor substrate 300 are disposed such that the plurality of light emitting diodes 130 on the wafer 200 and the plurality of bumps 331 of the donor substrate 300 are opposite to each other, the wafer 200 and the donor substrate 300 may be aligned. Specifically, a center of the first alignment key AK1 of the wafer 200 and a center of the first alignment bump 333 of the donor substrate 300 are aligned to align the wafer 200 and the donor substrate 300.

Referring to FIG. 16, next, in the step S132 of bonding the wafer and the donor substrate, the wafer 200 and the donor substrate 300 are bonded while maintaining a state in which alignment of the wafer 200 and the donor substrate 300 is completed.

Thereafter, in the step S133 of transferring the plurality of light emitting diodes disposed on the wafer onto the donor substrate, in a state in which the wafer 200 and the donor substrate 300 are bonded to be opposite to each other, laser may be selectively irradiated onto only one or more light emitting diodes 130 to be transferred onto the donor substrate 300, among the plurality of light emitting diodes 130. The one or more light emitting diodes 130 irradiated with the laser are detached from the wafer 200 to be transferred onto the plurality of bumps 331 of the donor substrate 300.

At this time, referring to FIGS. 17A and 17B, a repair alignment key AK2c among the plurality of second alignment keys AK2 of the wafer 200 may be also transferred onto the donor substrate 300. In the state in which the wafer 200 and the donor substrate 300 are bonded to be opposite to each other, the laser may be selectively irradiated only onto the repair alignment key AK2c. The repair alignment key AK2c is detached from the wafer 200 to be transferred onto the repair alignment area 334c of the second alignment bump 334 of the donor substrate 300.

Thereafter, in the step S134 of detaching the wafer and the donor substrate, the wafer 200 and the donor substrate 300 are detached and the donor substrate 300 onto which the light emitting diode 130 is transferred is discharged from the process equipment.

Next, referring to FIGS. 18 and 19, in the step S135 of aligning the donor substrate and the display panel, the donor substrate 300 on which the plurality of light emitting diodes 130 is disposed and the display panel PN are inserted into the process equipment and the donor substrate 300 and the display panel PN are aligned.

The repair alignment marks AM3a, AM3b, and AM3c of the display panel may match the plurality of repair alignment keys AK2c. A plurality of repair alignment marks AM3a, AM3b, and AM3c may be configured. For example, the repair alignment marks AM3a, AM3b, and AM3c may include a repair alignment mark AM3a for a red light emitting diode, a repair alignment mark AM3b for a green light emitting diode, and a repair alignment mark AM3c for a blue light emitting diode.

At this time, the donor substrate 300 and the display panel PN may be aligned based on the plurality of repair alignment keys AK2c of the donor substrate 300 and the plurality of repair alignment marks AM3a, AM3b, and AM3c of the display panel PN.

For example, the donor substrate 300 and the display panel PN may be aligned by overlapping the repair alignment key AK2c of the donor substrate 300 and the repair alignment marks AM3a, AM3b, and AM3c of the display panel PN.

Therefore, the plurality of light emitting diodes 130 and the electrode area EA of the display panel PN may overlap. To be more specific, the plurality of light emitting diodes 130 and a second electrode area EA2 of the electrode area EA of the display panel PN may overlap.

In the step S136 of bonding the donor substrate on which the plurality of light emitting diodes is disposed and the display panel, the display panel PN and the donor substrate 300 are bonded while maintaining a state in which alignment of the display panel PN and the donor substrate 300 is completed.

Next, in the step S137 of transferring at least one light emitting diode corresponding to a defective transferring area onto the display panel, in a state in which the display panel PN and the donor substrate 300 are bonded to be opposite to each other, laser may be selectively irradiated only onto at least one light emitting diode 130 corresponding to the defective transferring area. The laser-irradiated at least one light emitting diode 130 is detached from the donor substrate 300 to be transferred onto the second electrode area EA2 of the display panel PN.

For example, since it is determined that the defective light emitting diode 130′ is disposed in an electrode area EA disposed in a second row in FIG. 19, at least one light emitting diode 130 is transferred onto the second electrode area EA among the electrode area EA disposed in the second row corresponding to the defective transferring area.

At this time, the repair alignment key AK2c among the plurality of second alignment keys AK2 of the donor substrate 300 may be also transferred onto the display panel PN. In the state in which the donor substrate 300 and the display panel PN are bonded to be opposite to each other, the laser may be selectively irradiated only onto the repair alignment key AK2c. The repair alignment key AK2c is detached from the donor substrate 300 to be transferred onto any one of the repair alignment marks AM3a, AM3b, and AM3c of the display panel PN.

For reference, the repair alignment marks AM3a, AM3b, and AM3c may include a repair alignment mark AM3a for a red light emitting diode, a repair alignment mark AM3b for a green light emitting diode, and a repair alignment mark AM3c for a blue light emitting diode.

Specifically, referring to FIGS. 18 and 19, when it is assumed that the plurality of light emitting diodes 130 is red light emitting diodes, the repair alignment key AK2c may be transferred onto the repair alignment mark AM3a for the red light emitting diode(s).

Thereafter, in the step S138 of detaching the display panel and the donor substrate, the display panel PN and the donor substrate 300 are detached and the donor substrate 300 onto which the light emitting diode 130 is transferred is discharged from the process equipment.

Accordingly, the repair transfer process S130 may be completed by primarily transferring the plurality of light emitting diodes 130 from the wafer 200 to the donor substrate 300 and secondarily transferring at least one of the plurality of light emitting diodes 130 transferred onto the donor substrate 300 onto the display panel PN.

Unlike the present disclosure, when the repair alignment key AK2c which is separately formed from the wafer 200 is not formed, there is a process inconvenience to separately find a main repair alignment key which is not transferred, among the main repair alignment keys AK2a and AK2b and perform the repair transfer using the found main repair alignment key.

As described above, in a manufacturing process of a display device according to one or more example embodiments of the present disclosure, the repair transfer process S130 may be performed using a repair alignment key AK2c which is separately formed on the wafer 200.

Accordingly, in the manufacturing process of the display device according to one or more example embodiments of the present disclosure, it is not necessary to separately find the main repair alignment key which is not transferred, among the main repair alignment keys AK2a and AK2b during the repair transfer process.

Accordingly, in the manufacturing process of a display device according to one or more example embodiments of the present disclosure, an efficiency of a repair transfer process may be increased.

Further, in the manufacturing process of a display device according to one or more example embodiments of the present disclosure, the repair transfer process S130 is performed by means of the repair alignment key AK2c formed separately on the wafer 200. Therefore, the light emitting diode for repair may be transferred while maintaining a predetermined interval from the defective light emitting diode.

Therefore, an alignment precision between a plurality of light emitting diodes of a display device manufactured by the manufacturing process of a display device according to one or more example embodiments of the present disclosure may be improved.

With the above-described effect, in the manufacturing process of a display device according to one or more example embodiments of the present disclosure, a productivity of the display device and a yield of the manufacturing process may be improved.

Various examples and aspects of the present disclosure are described below. These are provided as examples, and do not limit the scope of the present disclosure.

In one or more aspects, an electrode area EA may include one or more electrode areas EA. In one or more aspects, a first electrode area EA1 may include one or more first electrode areas EA1. In one or more aspects, a second electrode area EA2 may include one or more second electrode areas EA2.

In one or more aspects, a pixel PX (or each pixel, a pixel area, or each pixel area) may include electrode areas EA. In one or more aspects, each electrode area EA may have a same size and a same shape. In one or more aspects, the electrode areas EA may be arranged in rows and columns. In one or more aspects, each electrode area EA (or at least a portion of each electrode area EA) may be within a region defined by a corresponding row and a corresponding column.

In one or more aspects, each electrode area EA may include a first electrode area EA1 and a second electrode area EA2. In one or more aspects, each set of a first electrode area EA1 and a second electrode area EA2 (or each set of at least a portion of a first electrode area EA1 and at least a portion of a second electrode area EA2) may be within a region defined by a corresponding row and a corresponding column.

In one or more aspects, a plurality of light emitting diodes 130 may be arranged in rows and columns. In one or more aspects, each of a plurality of light emitting diodes 130 may be disposed in a corresponding electrode area EA.

In one or more aspects, a first alignment key AK1 may include one or more first alignment keys AK1. In one or more aspects, a first main alignment key AK2a may include one or more first main alignment keys AK2a. In one or more aspects, a second main alignment key AK2b may include one or more second main alignment keys AK2b. In one or more aspects, a repair alignment key AK2c may include one or more repair alignment keys AK2c.

In one or more aspects, a first main alignment mark AM1a, AM1b, or AM1c may include one or more first main alignment marks. In one or more aspects, a second main alignment mark AM2a, AM2b, or AM2c may include one or more second main alignment marks. In one or more aspects, a repair alignment mark AM3a, AM3b, or AM3c may include one or more repair alignment marks.

In one or more aspects, a transferring position may be (or may correspond to) a position on or at a wafer 200. In one or more aspects, a transferring position may be (or may correspond to) a position on or at a donor substrate 300. In one or more aspects, a transferring position may correspond to a position on or at a display panel PN. In one or more aspects, a defective transferring area may be (or may correspond to) an area on or at a wafer 200. In one or more aspects, a defective transferring area may be (or may correspond to) an area on or at a donor substrate 300. In one or more aspects, a defective transferring area may be (or may correspond to) an area on or at a display panel PN. In one or more aspects, a defective transferring area may be (or may correspond to) an electrode area EA on or at a display panel PN.

In one or more aspects, a wafer used for a main transfer process step S110 may be used as a wafer for a repair transfer process S130. In one or more aspects, a wafer used for a main transfer process step S110 may be different from a wafer used for a repair transfer process S130.

In one or more aspects, a plurality of light emitting diodes 130 being transferred from a wafer onto a donor substrate 300 at step S113 of the main transfer process step S110 may be different from a plurality of light emitting diodes 130 being transferred from a wafer onto the donor substrate 300 at step S133 of the repair transfer process step S130.

According to one or more aspects of the present disclosure, a display device 100 may include: a display panel PN; an active area AA and a non-active area NA surrounding the active area; and a plurality of pixels PX in the active area AA (see, e.g., FIGS. 1 to 3). Each pixel PX of the plurality of pixels PX may include electrode areas EA. Each electrode area EA of the electrode areas EA may include a first electrode area EA1 and a second electrode area EA2 adjacent to the first electrode area EA1. Positions of the first and second electrode areas EA1 and EA2 relative to each other may be the same for all of the electrode areas EA in the plurality of pixels PX. Each pixel PX of the plurality of pixels PX may include a plurality of light emitting diodes 130. Each light emitting diode 130 of the plurality of light emitting diodes 130 may be disposed in at least one of the first electrode area EA1 or the second electrode area EA2 of a corresponding electrode area EA. The plurality of pixels PX may include a first pixel. (see, e.g., FIGS. 2B, 4A, 4B, 14 and 19).

The plurality of light emitting diodes 130 of the first pixel may include at least one light emitting diode and other light emitting diodes.

The at least one light emitting diode of the first pixel (e.g., a light emitting diode 130 that is adjacent to the phantom depiction of the defective light emitting diode 130′ of FIG. 19) may be disposed in the second electrode area EA2 of the corresponding electrode area EA of the first pixel (e.g., at the second row and first column of the pixel in FIG. 19).

Each of the other light emitting diodes of the first pixel (e.g., light emitting diodes 130 at the first row and first three columns of the pixel in FIG. 19) may be disposed in the first electrode area EA1 of the corresponding electrode area EA of the first pixel. In one or more examples, each of the other light emitting diodes of the first pixel (e.g., light emitting diodes 130 at the first row and first three columns of the pixel in FIG. 19) is not disposed in the second electrode area EA2 of the corresponding electrode area EA of the first pixel.

In some examples, the plurality of light emitting diodes 130 of the first pixel may also include additional one or more light emitting diodes. Each of the additional one or more light emitting diodes of the first pixel (e.g., light emitting diodes 130 at the second row and second and third columns of the pixel in FIG. 19) may be disposed in the first electrode area EA1 and the second electrode area EA2 of the corresponding electrode area EA of the first pixel.

In this regard, the other light emitting diodes of the first pixel may have been formed onto the first electrode areas EA1 of the corresponding electrode areas EA of the display panel PN during the step S117 of a main transfer process S110. During a transfer failure determining step S120, a defective light emitting diode 130′ which is missed or misplaced from a transferring position in the main transfer process step S110 may be determined, and a position of the defective transferring area corresponding to the defective light emitting diode 130′ which is missed or misplaced from the transferring position may be determined.

In this example, the corresponding electrode area EA associated with the at least one light emitting diode of the first pixel may correspond to the defective transferring area. A light emitting diode (e.g., the defective light emitting diode 130′) may be absent or misplaced from the first electrode area EA1 of the corresponding electrode area EA that corresponds to the defective transferring area.

The at least one light emitting diode of the first pixel may be formed in the second electrode area EA2 of the corresponding electrode area EA of the first pixel during the step S137 of a repair transfer process step S130.

In one or more examples, the at least one light emitting diode of the first pixel and the other light emitting diodes of the first pixel may constitute all of the light emitting diodes in the first pixel. In one or more examples, the at least one light emitting diode of the first pixel, the other light emitting diodes of the first pixel, and additional one or more light emitting diodes of the first pixel may constitute all of the light emitting diodes in the first pixel.

In one or more aspects, the plurality of pixels PX may further include a second pixel adjacent to the first pixel. In this example, the second pixel may be free of defective transferring areas. Hence, in this example, each light emitting diode 130 of the second pixel may be disposed in the first electrode area EA1 of the corresponding electrode area EA of the second pixel but not in the second electrode area EA2 of the corresponding electrode area EA of the second pixel.

In one or more aspects, the plurality of light emitting diodes 130 of each of the first and second pixels may be disposed in the corresponding electrode areas EA arranged in rows and columns (see, e.g., FIGS. 2B, 14 and 19). In this example, FIG. 2B illustrates a plurality of pixels PX (e.g., a first pixel, a second pixel, and other pixels).

The at least one light emitting diode of the first pixel (e.g., a light emitting diode 130 in the second electrode area EA2 of the corresponding electrode area EA at the second row and first column of the pixel in FIG. 19) may be separated by a first distance from a light emitting diode at a corresponding row and a corresponding column (e.g., at the second row and first column) of the second pixel.

Each of the other light emitting diodes of the first pixel (e.g., light emitting diodes 130 at the first row and first three columns of the pixel in FIG. 19) may be separated by a second distance from a light emitting diode at a corresponding row and a corresponding column (at the first row and first three columns) of the second pixel. The second distance may be a pixel distance (e.g., D1 of FIG. 2B) between the first pixel and the second pixel. The first distance may be different from the second distance.

The display device may further include at least one repair alignment mark AM3a, AM3b, or AM3c disposed on the display panel PN and not overlapping the plurality of pixels. For example, FIG. 19 illustrates that repair alignment marks AM3a, AM3b, and AM3c do not overlap pixels in the pixel areas UPA, and FIG. 3 illustrates alignment marks AM are outside the pixel areas UPA.

The display device may also include at least one repair alignment key AK2c disposed on and overlapping the at least one repair alignment mark AM3a, AM3b, or AM3c (see, e.g., FIGS. 17A to 19). In an example, a shape of the at least one repair alignment key may be different from a shape of the at least one repair alignment mark. The at least one repair alignment key may be formed on the at least one repair alignment mark at a same time as when the at least one light emitting diode of the first pixel may be formed in the second electrode area of the corresponding electrode area of the first pixel (see, e.g., FIGS. 18 and 19).

According to one or more aspects of the present disclosure, a display device 100 may include: a display panel PN; an active area AA and a non-active area NA; and a plurality of pixels PX arranged in the active area AA, the plurality of pixels PX forming a matrix (see, e.g., FIGS. 1 to 3). Each pixel may include a plurality of light emitting diodes 130 arranged in rows and columns, the plurality of light emitting diodes 130 for emitting light. The plurality of pixels PX may include a first pixel and a second pixel adjacent to the first pixel. (see, e.g., FIGS. 2B, 4A, 4B, 14 and 19).

At least one light emitting diode of the first pixel (e.g., a light emitting diode 130 that is adjacent to the phantom depiction of the defective light emitting diode 130′ of FIG. 19 and that is located at the second row and first column of the pixel in FIG. 19) may be separated by a first distance from a light emitting diode at a corresponding row and a corresponding column (e.g., at the second row and first column) of the second pixel.

Each of the other light emitting diodes of the first pixel (e.g., light emitting diodes 130 at the first row and first three columns of the pixel in FIG. 19) may be separated by a second distance from a light emitting diode at a corresponding row and a corresponding column (at the first row and first three columns) of the second pixel. The first distance may be different from the second distance.

The plurality of pixels may further include a third pixel adjacent to the second pixel (see, e.g., FIG. 2B). In this example, the third pixel may be free of defective transferring areas. Each of the plurality of light emitting diodes 130 of the third pixel may be separated by a third distance from a light emitting diode at a corresponding row and a corresponding column of the second pixel.

Locations of the plurality of light emitting diodes relative to one another within the first pixel may form a first pattern (see, e.g., FIG. 19). Locations of the plurality of light emitting diodes relative to one another within the second pixel may form a second pattern. Locations of the plurality of light emitting diodes relative to one another within the third pixel may form a third pattern. The third distance may be the same as the second distance. The third pattern may be the same as the second pattern. The first pattern may be different from the second pattern at least as a result of the first distance being different from the second distance.

Further examples and aspects of the present disclosure are described below. These are provided as examples, and do not limit the scope of the present disclosure.

According to one or more aspects of the present disclosure, a manufacturing method of a display device may include: transferring a plurality of light emitting diodes onto a display panel using a main alignment key disposed on a wafer; determining a defective light emitting diode which is missed or misplaced from a transferring position; and transferring at least one light emitting diode for repairing the defective light emitting diode onto the display panel using a repair alignment key disposed on a second wafer, wherein the second wafer is same as or different from the wafer. In one or more aspects, a main transfer process may include transferring of the plurality of light emitting diodes onto the display panel using the main alignment key disposed on the wafer. In one or more aspects, a transfer failure determining process may include determining the defective light emitting diode which is missed or misplaced from the transferring position. In one or more aspects, a repair transfer process may include transferring the at least one light emitting diode for repairing the defective light emitting diode onto the display panel using the repair alignment key disposed on the second wafer, wherein the second wafer is same as or different from the wafer.

The transferring of the plurality of light emitting diodes may include aligning the wafer and a donor substrate, bonding the wafer and the donor substrate, transferring the plurality of light emitting diodes disposed on the wafer onto the donor substrate, detaching the wafer and the donor substrate from each other, aligning the donor substrate and the display panel, bonding the donor substrate on which the plurality of light emitting diodes is disposed and the display panel, transferring the plurality of light emitting diodes disposed on the donor substrate onto the display panel; and detaching the display panel and the donor substrate from each other.

In the aligning of the wafer and the donor substrate, the wafer and the donor substrate may be aligned based on a first alignment key of the wafer and a first alignment bump of the donor substrate.

In the transferring of the plurality of light emitting diodes disposed on the wafer onto the donor substrate, the main alignment key of a second alignment key of the wafer may be transferred onto a main alignment area of a second alignment bump of the donor substrate.

The main alignment key may include a first main alignment key and a second main alignment key, the main alignment area may include a first main alignment area and a second main alignment area, and in the transferring of the plurality of light emitting diodes disposed on the wafer onto the donor substrate, the first main alignment key of the second alignment key of the wafer may be transferred onto the first main alignment area of the second alignment bump of the donor substrate or the second main alignment key of the second alignment key of the wafer may be transferred onto the second main alignment area of the second alignment bump of the donor substrate.

In the aligning of the donor substrate and the display panel, the donor substrate and the display panel may be aligned based on the main alignment key transferred onto the donor substrate and a main alignment mark of the display panel.

In the transferring of the plurality of light emitting diodes disposed on the donor substrate onto the display panel, the plurality of light emitting diodes may be transferred onto a first electrode area of an electrode area of the display panel, and the main alignment key transferred onto the donor substrate may be transferred onto a main alignment mark of the display panel.

The main alignment key may include a first main alignment key and a second main alignment key, the main alignment mark may include a first main alignment mark and a second main alignment mark, and in the transferring of the plurality of light emitting diodes disposed on the donor substrate onto the display panel, the first main alignment key transferred onto the donor substrate may be transferred onto the first main alignment mark of the display panel or the second main alignment key transferred onto the donor substrate may be transferred onto the second main alignment mark of the display panel.

In the determining of the defective light emitting diode, a defective transferring area corresponding to the defective light emitting diode which is missed or is misplaced from the transferring position may be determined.

The transferring of the at least one light emitting diode for repairing the defective light emitting diode may include: aligning the second wafer and a donor substrate; bonding the second wafer and the donor substrate; transferring a second plurality of light emitting diodes disposed on the second wafer onto the donor substrate; detaching the second wafer and the donor substrate from each other; aligning the donor substrate and the display panel; bonding the donor substrate on which the second plurality of light emitting diodes is disposed and the display panel; transferring the at least one light emitting diode corresponding to the defective transferring area onto the display panel; and detaching the display panel and the donor substrate from each other.

In the aligning of the second wafer and the donor substrate, the second wafer and the donor substrate may be aligned based on a first alignment key of the wafer and a first alignment bump of the donor substrate.

In the transferring of the second plurality of light emitting diodes disposed on the second wafer onto the donor substrate, the repair alignment key of a second alignment key of the second wafer may be transferred onto a repair alignment area of a second alignment bump of the donor substrate.

In the aligning of the donor substrate and the display panel, the donor substrate and the display panel may be aligned based on the repair alignment key transferred onto the donor substrate and a repair alignment mark of the display panel.

In the transferring of the at least one light emitting diode corresponding to the defective transferring area onto the display panel, the at least one light emitting diode corresponding to the defective transferring area may be transferred onto a second electrode area of an electrode area of the display panel, and the repair alignment key transferred onto the donor substrate may be transferred onto a repair alignment mark of the display panel.

According to one or more aspects of the present disclosure, a display device may include: a display panel; an active area and a non-active area surrounding the active area; and a plurality of pixels in the active area. Each pixel may include electrode areas; each electrode area may include a first electrode area and a second electrode area adjacent to the first electrode area; positions of the first and second electrode areas relative to each other may be the same for all of the electrode areas; each pixel may include a plurality of light emitting diodes, and each light emitting diode may be disposed in at least one of the first electrode area or the second electrode area of a corresponding electrode area; the plurality of pixels may include a first pixel; at least one light emitting diode of the first pixel may be disposed in the second electrode area of the corresponding electrode area of the first pixel; and each of other light emitting diodes of the first pixel may be disposed in the first electrode area of the corresponding electrode area of the first pixel but not in the second electrode area of the corresponding electrode area of the first pixel.

The corresponding electrode area associated with the at least one light emitting diode may correspond to a defective transferring area, and a light emitting diode may be absent or misplaced from the first electrode area of the corresponding electrode area that corresponds to the defective transferring area.

The plurality of pixels may further include a second pixel adjacent to the first pixel, and each light emitting diode of the second pixel may be disposed in the first electrode area of the corresponding electrode area of the second pixel but not in the second electrode area of the corresponding electrode area of the second pixel.

The plurality of light emitting diodes of each of the first and second pixels may be disposed in the corresponding electrode areas arranged in rows and columns. The at least one light emitting diode of the first pixel may be separated by a first distance from a light emitting diode at a corresponding row and a corresponding column of the second pixel. Each of the other light emitting diodes of the first pixel may be separated by a second distance from a light emitting diode at a corresponding row and a corresponding column of the second pixel. The second distance may be a pixel distance between the first pixel and the second pixel. The first distance may be different from the second distance.

The display device may further include: at least one repair alignment mark disposed on the display panel and not overlapping the plurality of pixels; and at least one repair alignment key disposed on and overlapping the at least one repair alignment mark. A shape of the at least one repair alignment key may be different from a shape of the at least one repair alignment mark. The at least one repair alignment key may be formed on the at least one repair alignment mark at a same time as when the at least one light emitting diode of the first pixel may be formed in the second electrode area of the corresponding electrode area of the first pixel.

According to one or more aspects of the present disclosure, a display device may include: a display panel; an active area and a non-active area; and a plurality of pixels arranged in the active area, the plurality of pixels forming a matrix. Each pixel may include a plurality of light emitting diodes arranged in rows and columns, the plurality of light emitting diodes for emitting light; the plurality of pixels may include a first pixel and a second pixel adjacent to the first pixel; at least one light emitting diode of the first pixel may be separated by a first distance from a light emitting diode at a corresponding row and a corresponding column of the second pixel; each of the other light emitting diodes of the first pixel may be separated by a second distance from a light emitting diode at a corresponding row and a corresponding column of the second pixel; and the first distance may be different from the second distance.

The plurality of pixels may further include a third pixel adjacent to the second pixel. Each of the plurality of light emitting diodes of the third pixel may be separated by a third distance from a light emitting diode at a corresponding row and a corresponding column of the second pixel. Locations of the plurality of light emitting diodes relative to one another within the first pixel may form a first pattern. Locations of the plurality of light emitting diodes relative to one another within the second pixel may form a second pattern. Locations of the plurality of light emitting diodes relative to one another within the third pixel may form a third pattern. The third distance may be the same as the second distance. The third pattern may be the same as the second pattern. The first pattern may be different from the second pattern at least as a result of the first distance being different from the second distance.

Although the example embodiments of the present disclosure have been described in detail with reference to the accompanying drawings, the present disclosure is not limited thereto and may be embodied in many different forms without departing from the technical concept or scope of the present disclosure. Therefore, the example embodiments of the present disclosure are provided for illustrative purposes only but not intended to limit the technical concept or scope of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure. Thus, it is intended that the present disclosure covers the modifications and variations of this disclosure that come within the scope of the claims and their equivalents.

What is claimed is:

1. A manufacturing method of a display device, comprising:
transferring a plurality of light emitting diodes onto a display panel using a main alignment key disposed on a wafer;
determining a defective light emitting diode which is missed or misplaced from a transferring position; and
transferring at least one light emitting diode for repairing the defective light emitting diode onto the display panel using a repair alignment key disposed on a second wafer,
wherein the second wafer is same as or different from the wafer.

2. The manufacturing method of the display device according to claim 1,
wherein the transferring of the plurality of light emitting diodes includes:
aligning the wafer and a donor substrate;
bonding the wafer and the donor substrate;
transferring the plurality of light emitting diodes disposed on the wafer onto the donor substrate;
detaching the wafer and the donor substrate from each other;
aligning the donor substrate and the display panel;
bonding the donor substrate on which the plurality of light emitting diodes is disposed and the display panel;
transferring the plurality of light emitting diodes disposed on the donor substrate onto the display panel; and
detaching the display panel and the donor substrate from each other.

3. The manufacturing method of the display device according to claim 2,
wherein in the aligning of the wafer and the donor substrate, the wafer and the donor substrate are aligned based on a first alignment key of the wafer and a first alignment bump of the donor substrate.

4. The manufacturing method of the display device according to claim 2,
wherein in the transferring of the plurality of light emitting diodes disposed on the wafer onto the donor substrate, the main alignment key of a second alignment key of the wafer is transferred onto a main alignment area of a second alignment bump of the donor substrate.

5. The manufacturing method of the display device according to claim 4,
wherein:
the main alignment key includes a first main alignment key and a second main alignment key;
the main alignment area includes a first main alignment area and a second main alignment area; and
in the transferring of the plurality of light emitting diodes disposed on the wafer onto the donor substrate, the first main alignment key of the second alignment key of the wafer is transferred onto the first main alignment area of the second alignment bump of the donor substrate, or the second main alignment key of the second alignment key of the wafer is transferred onto the second main alignment area of the second alignment bump of the donor substrate.

6. The manufacturing method of the display device according to claim 4,
wherein in the aligning of the donor substrate and the display panel, the donor substrate and the display panel are aligned based on the main alignment key transferred onto the donor substrate and a main alignment mark of the display panel.

7. The manufacturing method of the display device according to claim 4,
wherein in the transferring of the plurality of light emitting diodes disposed on the donor substrate onto the display panel, the plurality of light emitting diodes is transferred onto a first electrode area of an electrode area of the display panel, and the main alignment key transferred onto the donor substrate is transferred onto a main alignment mark of the display panel.

8. The manufacturing method of the display device according to claim 7,
wherein:
the main alignment key includes a first main alignment key and a second main alignment key;
the main alignment mark includes a first main alignment mark and a second main alignment mark; and
in the transferring of the plurality of light emitting diodes disposed on the donor substrate onto the display panel, the first main alignment key transferred onto the donor substrate is transferred onto the first main alignment mark of the display panel, or the second main alignment key transferred onto the donor substrate is transferred onto the second main alignment mark of the display panel.

9. The manufacturing method of the display device according to claim 1,
wherein in the determining of the defective light emitting diode, a defective transferring area corresponding to the defective light emitting diode which is missed or is misplaced from the transferring position is determined.

10. The manufacturing method of the display device according to claim 9,
wherein the transferring of the at least one light emitting diode for repairing the defective light emitting diode includes:
aligning the second wafer and a donor substrate;
bonding the second wafer and the donor substrate;
transferring a second plurality of light emitting diodes disposed on the second wafer onto the donor substrate;
detaching the second wafer and the donor substrate from each other;
aligning the donor substrate and the display panel;
bonding the donor substrate on which the second plurality of light emitting diodes is disposed and the display panel;
transferring the at least one light emitting diode corresponding to the defective transferring area onto the display panel; and
detaching the display panel and the donor substrate from each other.

11. The manufacturing method of the display device according to claim 10,
wherein in the aligning of the second wafer and the donor substrate, the second wafer and the donor substrate are aligned based on a first alignment key of the wafer and a first alignment bump of the donor substrate.

12. The manufacturing method of the display device according to claim 10,
wherein in the transferring of the second plurality of light emitting diodes disposed on the second wafer onto the donor substrate, the repair alignment key of a second alignment key of the second wafer is transferred onto a repair alignment area of a second alignment bump of the donor substrate.

13. The manufacturing method of the display device according to claim 12,
wherein in the aligning of the donor substrate and the display panel, the donor substrate and the display panel are aligned based on the repair alignment key transferred onto the donor substrate and a repair alignment mark of the display panel.

14. The manufacturing method of the display device according to claim 12,
wherein in the transferring of the at least one light emitting diode corresponding to the defective transferring area onto the display panel, the at least one light emitting diode corresponding to the defective transferring area is transferred onto a second electrode area of an electrode area of the display panel, and the repair alignment key transferred onto the donor substrate is transferred onto a repair alignment mark of the display panel.

15. A display device, comprising:
a display panel;
an active area and a non-active area surrounding the active area; and
a plurality of pixels in the active area;
wherein:
each pixel comprises electrode areas;
each electrode area comprises a first electrode area and a second electrode area adjacent to the first electrode area;
positions of the first and second electrode areas relative to each other are same for all of the electrode areas;
each pixel comprises a plurality of light emitting diodes, and each light emitting diode is disposed in at least one of the first electrode area or the second electrode area of a corresponding electrode area;
the plurality of pixels comprises a first pixel;
at least one light emitting diode of the first pixel is disposed in the second electrode area of the corresponding electrode area of the first pixel; and
each of other light emitting diodes of the first pixel is disposed in the first electrode area of the corresponding electrode area of the first pixel but not in the second electrode area of the corresponding electrode area of the first pixel.

16. The display device according to claim 15, wherein:
the corresponding electrode area associated with the at least one light emitting diode corresponds to a defective transferring area; and
a light emitting diode is absent or misplaced from the first electrode area of the corresponding electrode area that corresponds to the defective transferring area.

17. The display device according to claim 15, wherein:
the plurality of pixels further comprises a second pixel adjacent to the first pixel; and
each light emitting diode of the second pixel is disposed in the first electrode area of the corresponding electrode area of the second pixel but not in the second electrode area of the corresponding electrode area of the second pixel.

18. The display device according to claim 17, wherein:
the plurality of light emitting diodes of each of the first and second pixels are disposed in the corresponding electrode areas arranged in rows and columns;
the at least one light emitting diode of the first pixel is separated by a first distance from a light emitting diode at a corresponding row and a corresponding column of the second pixel;
each of the other light emitting diodes of the first pixel is separated by a second distance from a light emitting diode at a corresponding row and a corresponding column of the second pixel;
the second distance is a pixel distance between the first pixel and the second pixel; and
the first distance is different from the second distance.

19. The display device according to claim 15, further comprising:
at least one repair alignment mark disposed on the display panel and not overlapping the plurality of pixels; and
at least one repair alignment key disposed on and overlapping the at least one repair alignment mark,
wherein:
a shape of the at least one repair alignment key is different from a shape of the at least one repair alignment mark; and
the at least one repair alignment key is formed on the at least one repair alignment mark at a same time as when the at least one light emitting diode of the first pixel is formed in the second electrode area of the corresponding electrode area of the first pixel.

20. A display device, comprising:
a display panel;
an active area and a non-active area; and
a plurality of pixels arranged in the active area, the plurality of pixels forming a matrix, wherein:
each pixel comprises a plurality of light emitting diodes arranged in rows and columns, the plurality of light emitting diodes for emitting light;
the plurality of pixels comprises a first pixel and a second pixel adjacent to the first pixel;
at least one light emitting diode of the first pixel is separated by a first distance from a light emitting diode at a corresponding row and a corresponding column of the second pixel;
each of the other light emitting diodes of the first pixel is separated by a second distance from a light emitting diode at a corresponding row and a corresponding column of the second pixel; and
the first distance is different from the second distance.

21. The display device according to claim 19, wherein:
the plurality of pixels further comprises a third pixel adjacent to the second pixel;
each of the plurality of light emitting diodes of the third pixel is separated by a third distance from a light emitting diode at a corresponding row and a corresponding column of the second pixel;
locations of the plurality of light emitting diodes relative to one another within the first pixel form a first pattern;
locations of the plurality of light emitting diodes relative to one another within the second pixel form a second pattern;
locations of the plurality of light emitting diodes relative to one another within the third pixel form a third pattern;
the third distance is same as the second distance;
the third pattern is same as the second pattern; and
the first pattern is different from the second pattern at least as a result of the first distance being different from the second distance.

22. The manufacturing method of the display device according to claim 8, wherein each of the first main alignment mark and the second main alignment mark of the display panel includes an alignment mark for a red light emitting diode of the plurality of light emitting diodes, an alignment mark for a green light emitting diode of the plurality of light emitting diodes, and an alignment mark for a blue light emitting diode of the plurality of light emitting diodes.
